(19) United States
(12) Patent Application Publication
(10) Pub. No.: US 2026/0134928 A1
(43) Pub. Date: May 14, 2026

(54) MEMORY SYSTEM AND METHOD OF CONTROLLING THE SAME

(71) Applicant: Kioxia Corporation, Tokyo (JP)

(72) Inventor: Tokumasa HARA, Kawasaki (JP)

(73) Assignee: Kioxia Corporation, Tokyo (JP)

(21) Appl. No.: 19/075,996

(22) Filed: Mar. 11, 2025

(30) Foreign Application Priority Data
Nov. 14, 2024 (JP) 2024-199081

(51) Int. Cl. G11C 16/34; G11C 11/56; G11C 16/04; G11C 16/10; G11C 16/26

(52) U.S. Cl. CPC G11C 16/3427; G11C 11/5628; G11C 11/5642; G11C 11/5671; G11C 16/0483; G11C 16/10; G11C 16/26; G11C 16/3459

(57) ABSTRACT

A memory system includes a memory and a controller. The memory includes: first memory cells; a first word line connected to these; second memory cells; and a second word line connected to these. The controller is configured to store first write data used for a write to first memory cells and second write data used for a write to second memory cells. The controller is configured to calculate rewrite data based on the first write data and the second write data. The memory is configured to perform: a first write operation of performing a write on first memory cells based on the first write data input from the controller; and a rewrite operation of performing a write on a part of first memory cells based on the rewrite data input from the controller.

### CROSS-REFERENCE TO RELATED APPLICATIONS

This application is based upon and claims the benefit of Japanese Patent Application No. 2024-199081, filed on Nov. 14, 2024, the entire contents of which are incorporated herein by reference.

### BACKGROUND

### Field

Embodiments described herein relate generally to a memory system and a method of controlling the same.

### Description of the Related Art

There has been known a memory system including a memory and a controller connected to the memory and connectable to a host device. In addition, there have been known various write methods to the memory.

### BRIEF DESCRIPTION OF THE DRAWINGS

FIG. 1 is a block diagram of a non-volatile semiconductor device illustrating an exemplary configuration of a first embodiment;

FIG. 2 is a block diagram of a memory system 10;

FIG. 3 is a circuit diagram illustrating an example of a three-dimensional structure NAND flash memory cell array MCA;

FIG. 4A is a cross-sectional view of a partial region of the three-dimensional structure NAND flash memory cell array MCA;

FIG. 4B is a cross-sectional view of an enlarged region R1 illustrated in FIG. 4A;

FIG. 5 is a drawing illustrating an example of regions of a threshold voltage;

FIG. 6 is a drawing illustrating 3-bit/Cell data coding;

FIG. 7 is a flowchart illustrating a processing procedure of a page read;

FIGS. 8A to 8H are drawings illustrating transitions of read voltages for word lines in the page read;

FIG. 9 is a drawing illustrating threshold distributions when all bits are simultaneously programmed;

FIGS. 10A and 10B are flowcharts illustrating examples of a write order in a block BLK when all bits are simultaneously programmed;

FIG. 11 is a drawing illustrating an example of an order of selecting word lines WL in programming when all bits are simultaneously programmed;

FIG. 12 is a drawing illustrating threshold distributions after programming in Foggy-Fine programming;

FIG. 13 is a drawing illustrating a programming order of the Foggy-Fine programming;

FIG. 14 is a flowchart illustrating an example of the programming order for one entire block BLK in the first embodiment;

FIGS. 15A and 15B are drawings illustrating examples

of the order of selecting the word lines WL in programming in the first embodiment;

FIG. 16 is a drawing illustrating threshold distributions after programming in the first embodiment;

FIG. 17 is an example of combinations of threshold regions between target cells and adjacent cells that are write targets for third-stage programming in the first embodiment;

FIG. 18 is a control flow diagram of write data in the first embodiment;

FIG. 19 is a drawing illustrating threshold distributions after programming in a second embodiment;

FIG. 20 is an example of combinations of threshold regions between target cells and adjacent cells that are write targets for third-stage programming in the second embodiment;

FIG. 21 is a control flow diagram of write data in the second embodiment;

FIG. 22 is a drawing illustrating threshold distributions after programming in a third embodiment;

FIG. 23 is an example of combinations of threshold regions between target cells and adjacent cells that are write targets for third-stage programming in the third embodiment;

FIG. 24 is a control flow diagram of write data in the third embodiment; and

FIG. 25 is a drawing illustrating an example of the order of selecting the word lines WL in programming in the third embodiment.

### DETAILED DESCRIPTION

A memory system according to one embodiment comprises a memory and a controller connected to the memory. The memory includes: a plurality of first memory cells; a first word line connected to the plurality of first memory cells; a plurality of second memory cells; and a second word line connected to the plurality of second memory cells. The controller is configured to be able to store first write data used for a write to the plurality of first memory cells and second write data used for a write to the plurality of second memory cells. The write is performed after the write to the plurality of first memory cells. The controller is configured to be able to calculate rewrite data based on the first write data and the second write data. The memory is configured to be able to perform: a first write operation of performing a write on the plurality of first memory cells based on the first write data input from the controller; and a rewrite operation of performing a write on a part of the plurality of first memory cells based on the rewrite data input from the controller.

Next, memory systems according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on the substrate side of this configuration. An upper surface and an upper end of a certain configuration mean a surface and an end portion on a side opposite to the substrate of this configuration. A surface intersecting with the X-direction or the Y-direction is referred to as a side surface and the like.

### First Embodiment

### Configuration

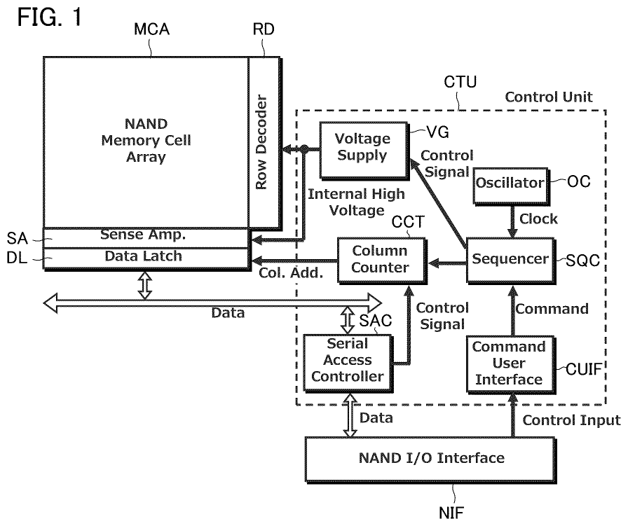

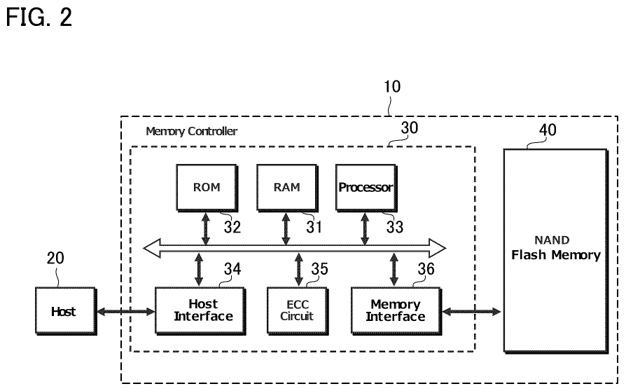

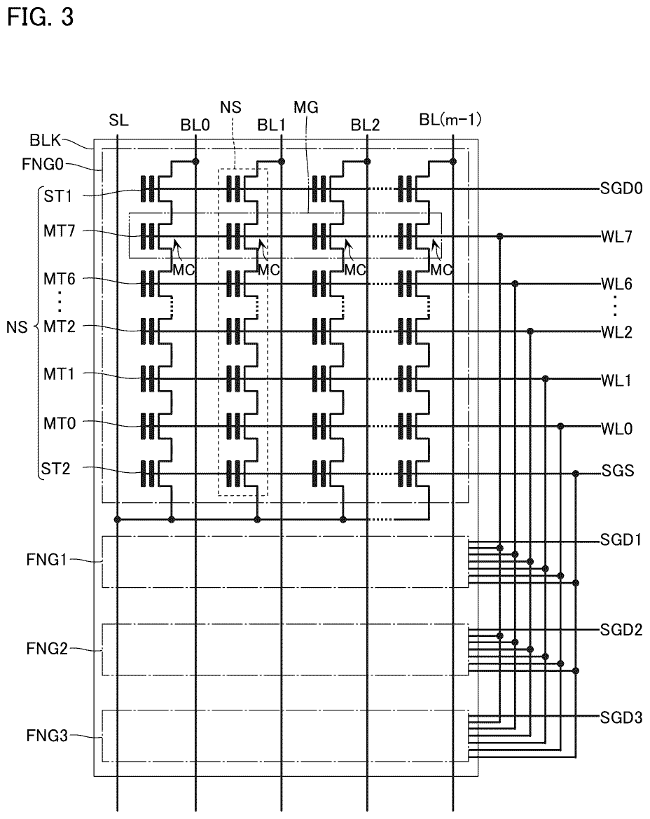

FIG. 1 is a block diagram of a non-volatile semiconductor device (non-volatile memory) illustrating an exemplary configuration of a first embodiment. FIG. 2 is a block diagram of a memory system 10. FIG. 3 is a circuit diagram illustrating an example of a three-dimensional structure NAND flash memory cell array MCA.

A non-volatile semiconductor memory device (non-volatile memory) is a memory that stores data in a non-volatile manner, such as a NAND flash memory 40. In this embodiment, the non-volatile semiconductor memory device is described as a NAND flash memory 40 having memory cells MC configured to be able to store three bits per memory cell MC, that is, a 3-bit/Cell (TLC: Triple Level Cell) NAND flash memory 40.

The non-volatile semiconductor memory device has memory cells MC three-dimensionally constructed and arrayed. In this specification, a plurality of memory cells MC connected to one word line WL in common and selected simultaneously by one select gate line SGD are defined as a physical memory cell group MG (FIG. 3). In this embodiment, the non-volatile semiconductor memory device is, for example, a 3-bit/Cell NAND flash memory 40, and one physical memory cell group MG corresponds to three pages. The three respective bits of each memory cell MC correspond to these three pages. In this specification, these three pages are referred to as a Lower page, a Middle page, and an Upper page.

The non-volatile semiconductor memory device illustrated in FIG. 1, for example, the NAND flash memory 40, includes a NAND I/O interface NIF, a control unit CTU, a NAND flash memory cell array MCA (memory cell MC unit), and a data latch unit DL. The non-volatile semiconductor memory device is, for example, formed on a semiconductor substrate (for example, a silicon substrate) and formed into a chip.

The control unit CTU controls an operation of the NAND flash memory 40 based on commands and the like from a memory controller 30 via the NAND I/O interface NIF. Specifically, when a write request is input, the control unit CTU controls to write the data requested for a write to a specified address on the NAND flash memory cell array MCA. In addition, when a read request is input, the control unit CTU controls to read the data requested for a read from the NAND flash memory cell array MCA and to output it to the memory controller 30 via the NAND I/O interface NIF.

The data latch unit DL is a buffer that temporarily stores the data input from the memory controller 30 during a write to the NAND flash memory cell array MCA or temporarily stores the data read from the NAND flash memory cell array MCA. In general, the data latch unit DL requires data latches, the number of rows of which is equal to the number of bits that can be latched in one cell plus one. In this embodiment, the data latch unit DL has four rows of data latches because of 3 bits/Cell. A data latch is a circuit configured of, for example, a latch circuit with two inverter circuits connected, and the like. These four respective rows of data latches are referred to as data latches XDL, ADL, BDL, CDL. The data latches XDL, ADL, BDL, CDL can transfer data to one another. Of these, only the data latch XDL is directly connected to a serial access controller SAC and can directly input and output data. The data latch XDL constitutes a page buffer.

The control unit CTU has an oscillator OC, a sequencer SQC, a command user interface CUIF, a voltage supply unit VG, a column counter CCT, and the serial access controller SAC.

In addition, the NAND flash memory cell array MCA has a row decoder RD and a sense amplifier SA.

The NAND I/O interface NIF is a circuit for transmitting and receiving an IO signal and a control signal to and from the memory controller 30.

Of a command, an address, and data received from the memory controller 30 via an I/O signal line, the command user interface CUIF acquires the command and the address based on the control signal. The command user interface CUIF is a circuit that passes the acquired command and address to the sequencer SQC.

The oscillator OC is a circuit that generates a clock. The clock generated by the oscillator OC is supplied to each component, including the sequencer SQC.

The sequencer SQC is a state machine driven by the clock supplied from the oscillator OC. The sequencer SQC controls access to the NAND flash memory cell array MCA and the like. For example, the sequencer SQC issues a command to control various internal voltages, operation timing, and the like in response to the command received from the command user interface CUIF. In addition, the sequencer SQC supplies a block address and a page address included in the address received from the command user interface CUIF to the row decoder RD. Furthermore, the sequencer SQC supplies a column address included in the address received from the command user interface CUIF to the column counter CCT.

The voltage supply unit VG is a circuit that generates various internal voltages applied to word lines WL and various internal voltages applied to bit lines BL and applies them to the row decoder RD and the sense amplifier SA. The column counter CCT sequentially increments the column address in accordance with the control signal supplied from the serial access controller SAC, starting with the column address supplied from the sequencer SQC in a program operation or a read operation.

The page buffer is a circuit that sequentially stores the data received from the serial access controller SAC in the above-described column address region specified by the column counter CCT in the program operation. In addition, in the read operation, the page buffer sequentially sends the data with the column address specified by the above-described column address among the stored data to the serial access controller SAC.

The serial access controller SAC is a circuit that stores the data received serially from the NAND I/O interface NIF for each bit width of the IO signal line in the page buffer in the program operation. In addition, in the read operation, the serial access controller SAC sends the data received serially from the page buffer for each bit width of the IO signal line to the NAND I/O interface NIF.

The row decoder RD is a circuit that decodes the block address and the page address and selects the word line WL corresponding to a page that is an access target contained in the block BLK to be accessed in the program operation and the read operation. Each row decoder RD applies an appropriate voltage to the selected word line WL and unselected word lines WL.

The sense amplifier SA is a circuit that transfers corresponding data stored in the page buffer to a memory cell transistor MT in the program operation, and senses data read from the selected word line WL to the bit lines BL and stores the obtained data in the page buffer in the read operation. The data stored in the page buffer is sent to the memory controller 30 via the serial access controller SAC and the NAND I/O interface NIF.

FIG. 2 illustrates the memory system 10 using the NAND flash memory 40. The memory controller 30 controls a write of data to the NAND flash memory 40 in accordance with a write command from a host 20. In addition, the memory controller 30 controls a read of data from the NAND flash memory 40 in accordance with a read command from the host 20. The memory controller 30 includes a Random Access Memory (RAM) 31, a Read Only Memory (ROM) 32, a processor 33, a host interface 34, an Error Check and Correct (ECC) circuit 35, and a memory interface 36. The RAM 31, the ROM 32, the processor 33, the host interface 34, the ECC circuit 35, and the memory interface 36 are connected to one another by an internal bus.

The host interface 34 outputs a command, user data (write data), and the like received from the host 20 to the internal bus. In addition, the host interface 34 is a circuit that sends user data read from the NAND flash memory 40, a response from the processor 33, and the like to the host 20.

The memory interface 36 is a circuit that controls processing to write the user data and the like to the NAND flash memory 40 and processing to read the user data and the like from the NAND flash memory 40 based on instructions of the processor 33.

The processor 33 controls the memory controller 30 comprehensively. The processor 33 is, for example, a Central Processing Unit (CPU), a Micro Processing Unit (MPU), or the like. When the processor 33 receives a command from the host 20 via the host interface 34, it performs control in accordance with the command. For example, the processor 33 instructs the memory interface 36 to write the user data and parity to the NAND flash memory 40 in accordance with a command from the host 20. In addition, the processor 33 instructs the memory interface 36 to read the user data and parity from the NAND flash memory 40 in accordance with a command from the host 20. The processor 33 determines a storage region (memory region) on the NAND flash memory 40 for the user data accumulated in the RAM 31. The user data is stored in the RAM 31 via the internal bus.

The processor 33 executes the determination of a memory region for data in units of pages (page data), which are the units of a write. In this specification, the user data stored in one page of the NAND flash memory 40 is defined as unit data.

Unit data is generally encoded and stored in the NAND flash memory 40 as a code word. In this embodiment, encoding is not mandatory. While the memory controller 30 may store the unit data in the NAND flash memory 40 without encoding it, a configuration that performs encoding is illustrated as an exemplary configuration in this embodiment. When the memory controller 30 does not perform encoding, the page data is matched with the unit data. In addition, one code word may be generated based on one piece of unit data, or one code word may be generated based on division data into which unit data is divided. Further, one code word may be generated using a plurality of pieces of unit data.

The processor 33 determines a memory region of the NAND flash memory 40 to be written to for each piece of unit data. A physical address is assigned to the memory region of the NAND flash memory 40. The processor 33 manages the memory region to which unit data is written using the physical address. The processor 33 specifies the determined memory region (physical address) and instructs the memory interface 36 to write user data to the NAND flash memory 40. The processor 33 manages a correspondence between a logical address of user data (a logical address managed by the host 20) and the physical address. When the processor 33 receives a read command including a logical address from the host 20, it identifies the physical address corresponding to the logical address, specifies the physical address, and instructs the memory interface 36 to read user data.

The ECC circuit 35 is a circuit that encodes the user data stored in the RAM 31 and generates a code word. In addition, the ECC circuit 35 decodes the code word read from the NAND flash memory 40. While FIG. 2 illustrates an exemplary configuration in which the memory controller 30 includes each of the ECC circuit 35 and the memory interface 36, the ECC circuit 35 may be integrated into the memory interface 36 or the NAND flash memory 40.

The RAM 31 temporarily stores the user data received from the host 20 until it is stored in the NAND flash memory 40 and temporarily stores the data read from the NAND flash memory 40 until it is sent to the host 20. For example, the RAM 31 is a general-purpose memory, such as a Static Random Access Memory (SRAM) and a Dynamic Random Access Memory (DRAM).

When a write request is received from the host 20, the memory system 10 operates as follows. The processor 33 temporarily stores write data in the RAM 31. The processor 33 reads the data stored in the RAM 31 and inputs it to the ECC circuit 35. The ECC circuit 35 encodes the input data and inputs a code word into the memory interface 36. The memory interface 36 writes the input code word to the NAND flash memory 40.

When a read request is received from the host 20, the memory system 10 operates as follows. The memory interface 36 inputs a code word read from the NAND flash memory 40 to the ECC circuit 35. The ECC circuit 35 decodes the input code word and stores the decoded data in the RAM 31. The processor 33 sends the data stored in the RAM 31 to the host 20 via the host interface 34. Note that the NAND flash memory 40 may be connected to a plurality of chips, and the NAND flash memory 40 and the memory interface 36 can be connected via an interface chip that has a role in relaying data and control signals.

The configuration of the memory controller 30 illustrated in FIG. 2 is an example, and it can take various other derivative forms, such as the internal bus being divided or hierarchically structured or additional function blocks being connected.

FIG. 3 illustrates a circuit configuration of one block BLK among a plurality of blocks BLK in the three-dimensional structure NAND flash memory cell array MCA. Other blocks BLK in the NAND flash memory cell array MCA have the same circuit configuration as FIG. 3.

As illustrated in FIG. 3, the block BLK has, for example, four fingers FNG (FNG0 to FNG3). Each of the fingers FNG includes a plurality of NAND strings NS. Each of the NAND strings NS has, for example, eight memory cell transistors MT (MT0 to MT7) that are connected in cascade and select transistors ST1, ST2. In this specification, each finger FNG may be referred to as a string St. Note that the number of memory cell transistors MT in a NAND string NS is not limited to eight.

The memory cell transistors MT are placed between the select transistors ST1, ST2 such that their current paths are connected in series. The current path of the memory cell transistor MT7 on one end side of this series connection is connected to one end of the current path of the select transistor ST1, and the current path of the memory cell transistor MT0 on the other end is connected to one end of the current path of the select transistor ST2.

Respective gates of the select transistors ST1 of the fingers FNG0 to FNG3 are connected in common to the select gate lines SGD0 to SGD3, respectively. On the other hand, gates of the select transistors ST2 are connected in common to the same select gate line SGS between the plurality of fingers FNG. In addition, control gates of the memory cell transistors MT0 to MT7 in the same block BLK are connected in common to word lines WL0 to WL7, respectively. That is, while the word lines WL0 to WL7 and the select gate line SGS are connected in common between the plurality of fingers FNG0 to FNG3 in the same block BLK, the select gate lines SGD are independent for each of the fingers FNG0 to FNG3 even in the same block BLK.

The word lines WL0 to WL7 are connected to control gate electrodes of the memory cell transistors MT0 to MT7 constituting the NAND strings NS, respectively. In addition, an i-th memory cell transistor MTi (i is an integer from 0 to 7), counting from one side in each NAND string NS in the same finger FNG, is connected in common to an i-th word line WLi in a similar manner. That is, the control gate electrodes of the memory cell transistors MTi on the same row in the block BLK are connected to the same word line WLi. Each NAND string NS is connected to the word line WLi and also to the bit lines BL. Each memory cell MC in each NAND string NS is identifiable by an address identifying the word line WLi and the select gate lines SGD0 to SGD3 and an address identifying the bit lines BL.

As described above, the data of the memory cells MC (memory cell transistors MT) in the same block BLK is erased collectively. On the other hand, a read and a write of data are performed in units of physical memory cell groups MG. One physical memory cell group MG includes a plurality of memory cells MC connected to one word line WLi and belonging to one finger FNG. The memory controller 30 performs a write (programming) in units of all memory cells MC connected to one word line WL in one finger FNG. Therefore, the units for the amount of data to be programmed by the memory controller 30 are three bits×(the number of bit lines BL). The units that identify these three bits are referred to as pages.

During a read operation and a program operation, one word line WLi and one select gate line SGD are selected according to a physical address, and a physical memory cell group MG is selected. In this specification, writing data to the memory cell MC is referred to as programming as necessary.

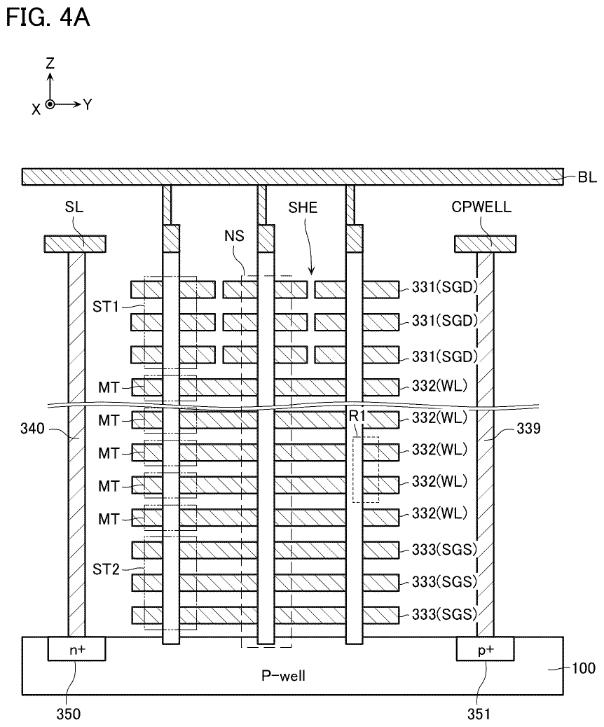

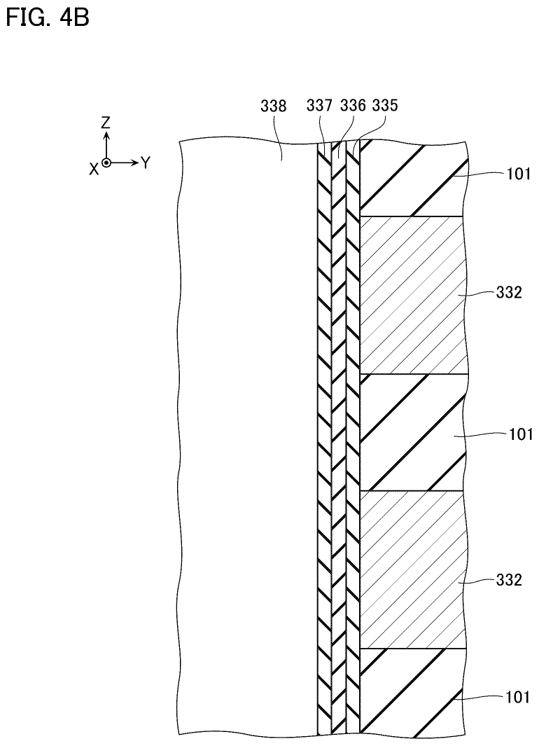

FIG. 4A is a cross-sectional view of a partial region of the three-dimensional structure NAND flash memory cell array MCA. FIG. 4B is a cross-sectional view of an enlarged region R1 illustrated in FIG. 4A. As illustrated in FIG. 4A, a plurality of NAND strings NS are formed on a p-type well region P-well. That is, a plurality of wiring layers 333 functioning as the select gate lines SGS, a plurality of wiring layers 332 functioning as the word lines WL, and a plurality of wiring layers 331 functioning as the select gate lines SGD are formed on the p-type well region P-well. Additionally, memory holes, which penetrate these wiring layers 331, 332, 333 and reach the p-type well region P-well, are formed.

As illustrated in FIG. 4B, a block insulating film 335, an electric charge accumulating layer 336, and a gate insulating film 337 are sequentially formed on a side surface of the memory hole, and further, a conductive film 338 is embedded in the memory hole. The conductive film 338 functions as a current path of the NAND string NS and is a region where a channel is formed during operations of the memory cell transistors MT and the select transistors ST1 and ST2. As illustrated in FIG. 4B, for example, insulating layers 101 of silicon oxide (SiO₂) or the like may be disposed between the wiring layers 331, 332, 333.

In each NAND string NS, the select transistor ST2, the plurality of memory cell transistors MT, and the select transistor ST1 are sequentially stacked on the p-type well region P-well. A wiring layer functioning as the bit line BL is formed on an upper end of the conductive film 338.

Furthermore, an n+ type impurity diffusion layer 350 and a p+ type impurity diffusion layer 351 are formed on a surface of the p-type well region P-well. A contact plug 340 is formed on the n+ type impurity diffusion layer 350, and a wiring layer functioning as a source line SL is formed on the contact plug 340. In addition, a contact plug 339 is formed on the p+ type impurity diffusion layer 351, and a wiring layer functioning as a well wiring CPWELL is formed on the contact plug 339.

A plurality of the above configurations illustrated in FIG. 4A are arranged in a depth direction of the paper surface of FIG. 4A, and one finger FNG is formed by an aggregation of a plurality of NAND strings NS arranged in a row in the depth direction. Other fingers FNG are formed, for example, in a left and right direction of FIG. 4A. While the four fingers FNG0 to FNG3 are illustrated in FIG. 3, an example in which three fingers FNG are placed between the contact plugs 339, 340 is illustrated in FIG. 4A.

This embodiment is applicable not only to the memory cells MC with a three-dimensional structure but also to those with a two-dimensional structure.

### Threshold Distributions of Non-Volatile Memory

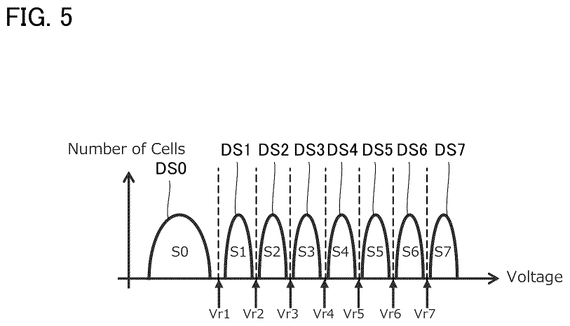

FIG. 5 is a drawing illustrating an example of regions of a threshold voltage. The horizontal axis of FIG. 5 indicates the threshold voltage, and the vertical axis indicates the number of memory cells. In FIG. 5, an example of the threshold distributions of a 3-bit/Cell non-volatile memory is illustrated. In the non-volatile memory, information is stored by an electric charge amount accumulated in the electric charge accumulating layer 336 of the memory cell MC. Each memory cell MC has a threshold voltage according to the electric charge amount. Then, a plurality of data values stored in the memory cell MC are mapped to a respective plurality of regions of the threshold voltage (threshold regions).

In FIG. 5, mountain-shaped distributions DS0, DS1, DS2, DS3, DS4, DS5, DS6, DS7 indicate threshold distributions in eight regions S0 to S7 of the threshold voltage, respectively. Thus, each memory cell MC has threshold distributions partitioned by seven boundaries. In this embodiment, a region where the threshold voltage is equal to or less than a voltage Vr1 is referred to as the region S0. A region where the threshold voltage is greater than the voltage Vr1 and equal to or less than a voltage Vr2 is referred to as the region S1. A region where the threshold voltage is greater than the voltage Vr2 and equal to or less than a voltage Vr3 is referred to as the region S2. A region where the threshold voltage is greater than the voltage Vr3 and equal to or less than a voltage Vr4 is referred to as the region S3. In addition, in this embodiment, a region where the threshold voltage is greater than the voltage Vr4 and equal to or less than a voltage Vr5 is referred to as the region S4. A region where the threshold voltage is greater than the voltage Vr5 and equal to or less than a voltage Vr6 is referred to as the region S5. A region where the threshold voltage is greater than the voltage Vr6 and equal to or less than a voltage Vr7 is referred to as the region S6. A region where the threshold voltage is greater than the voltage Vr7 is referred to as the region S7. Further, the threshold distributions corresponding to the regions S0, S1, S2, S3, S4, S5, S6, S7 are referred to as the distributions DS0, DS1, DS2, DS3, DS4, DS5, DS6, DS7, respectively. The voltage Vr1 to the voltage Vr7 are threshold voltages that serve as the boundaries of the respective regions.

In the non-volatile memory, a plurality of data values are mapped to a respective plurality of threshold regions (that is, threshold distributions) of the memory cell MC. This mapping is referred to as data coding. This data coding is preliminarily defined, and during a write (programming) of data, an electric charge is injected into the memory cell MC so that the threshold voltage falls within the threshold region corresponding to the stored data value in accordance with the data coding. During a read, a read voltage is applied to the memory cell MC, and the data is determined by whether the threshold of the memory cell MC is lower or higher than the read voltage. When the threshold voltage is lower than the read voltage, it is in an “erase” state, and the data value is defined as “1”. When the threshold voltage is greater than or equal to the read voltage, it is in a “programmed” state, and the data is defined as “0”.

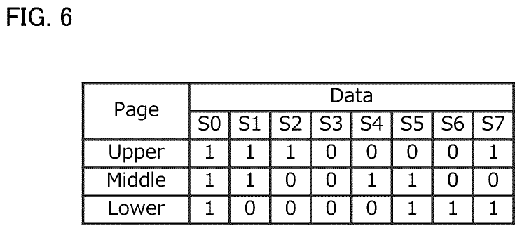

FIG. 6 is a drawing illustrating 3-bit/Cell data coding. In this embodiment, the eight threshold distributions (threshold regions) illustrated in FIG. 5 are mapped to eight respective 3-bit data values. A relationship between the threshold voltage and the data values of the bits corresponding to the Upper, Middle, and Lower pages is as follows.
The memory cells MC, whose threshold voltages are in the region S0, are in a state where “111” is stored.
The memory cells MC, whose threshold voltages are in the region S1, are in a state where “110” is stored.
The memory cells MC, whose threshold voltages are in the region S2, are in a state where “100” is stored.
The memory cells MC, whose threshold voltages are in the region S3, are in a state where “000” is stored.
The memory cells MC, whose threshold voltages are in the region S4, are in a state where “010” is stored.
The memory cells MC, whose threshold voltages are in the region S5, are in a state where “011” is stored.
The memory cells MC, whose threshold voltages are in the region S6, are in a state where “001” is stored.
The memory cells MC, whose threshold voltages are in the region S7, are in a state where “101” is stored.

Thus, the state of the three bits of data of each memory cell MC can be expressed for each threshold voltage region. When a memory cell MC is in an unwritten state (an “erased” state), the threshold voltage of the memory cell MC is in the region S0. In addition, in the data coding illustrated here, only one bit of data changes between any two adjacent states, as in a case where the data “111” is stored in the region S0 state, and the data “101” is stored in the region S1 state. Thus, the coding illustrated in FIG. 6 is Gray code in which only one bit of data changes between any two adjacent regions.

In the coding of this embodiment illustrated in FIG. 6, the threshold voltages that serve as the boundaries for determining a bit value of each page are as follows.
The threshold voltages that serve as the boundaries for determining the bit value of the Upper page are the voltages Vr3, Vr7.
The threshold voltages that serve as the boundaries for determining the bit value of the Middle page are the voltages Vr2, Vr4, Vr6.
The threshold voltages that serve as the boundaries for determining the bit value of the Lower page are the voltages Vr1, Vr5.

Thus, the numbers of threshold voltages that serve as the boundaries for determining the bit values (hereinafter referred to as the numbers of boundaries) are 2, 3, and 2 for the Lower page, the Middle page, and the Upper page, respectively. This coding is referred to as a 2-3-2 coding, using the respective numbers of boundaries for the Lower page, the Middle page, and the Upper page.

In this embodiment, this 2-3-2 coding is used as an example to explain. The mapping between the plurality of threshold regions and the data values of the memory cells MC can be expressed by different data coding, but indicating all is omitted. What kind of data coding is selected does not matter in this embodiment, but data coding that has a small bias in the number of boundaries distributed to each page is generally selected. In that case, the bias in the number of boundaries between pages is small, resulting in a smaller bias in a bit error rate between pages. This is because most of the causes of bit errors are caused by a threshold changing to adjacent threshold regions, and pages having a greater number of boundaries result in an increased number of bit errors. Since this leads to the need to enhance ECC correction capability necessary to correct errors in page data even when the error rate as the memory cell MC is the same, it is also effective to reduce deterioration in response performance of the memory system 10 to a write request or a read request from the host 20, cost, and power consumption. In addition, a bias in read rate caused by the bias in the number of boundaries is also reduced.

### Read Operation

Next, page read processing is described. According to the 2-3-2 data coding illustrated in FIG. 6, there are two boundaries between threshold states where Lower page data changes. Accordingly, the control unit CTU (FIG. 1) determines the data depending on which of the three ranges separated by the boundaries the threshold is located in. For example, when the threshold voltage is less than the voltage Vr1, the control unit CTU performs a control to output “1” as the data of a memory cell MC. When the threshold voltage is greater than the voltage Vr5, the control unit CTU performs a control to output “1” as the data of the memory cell MC. In addition, when the threshold voltage is less than the voltage Vr5 and greater than the voltage Vr1, the control unit CTU performs a control to output “0” as the data of the memory cell MC. Since there are three boundaries between threshold states where physical Middle page data changes, the control unit CTU determines the read data value as “0” or “1” depending on which of the four ranges separated by those boundaries the threshold is located in. Since there are two boundaries between threshold states where Upper page data changes, the control unit CTU determines the read data value as “0” or “1” depending on which of the three ranges separated by those boundaries the threshold is located in.

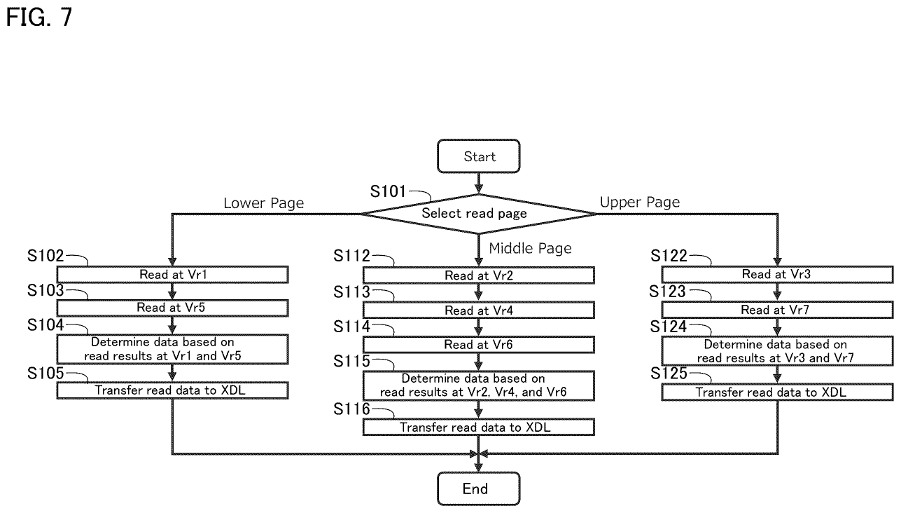

In the following, a specific processing procedure for a page read is described. FIG. 7 is a flowchart illustrating the processing procedure of the page read.

As illustrated in FIG. 7, the control unit CTU selects a read page (Step S101).

When the read page is the Lower page, the control unit CTU first performs a read at the voltage Vr1 (Step S102). Next, the control unit CTU performs a read at the voltage Vr5 (Step S103). Then, the control unit CTU determines the value of the read data as “0” or “1” based on a read result at the voltage Vr1 and a read result at the voltage Vr5 (Step S104). The control unit CTU transfers this one page of data from the sense amplifier SA to the data latch XDL (Step S105).

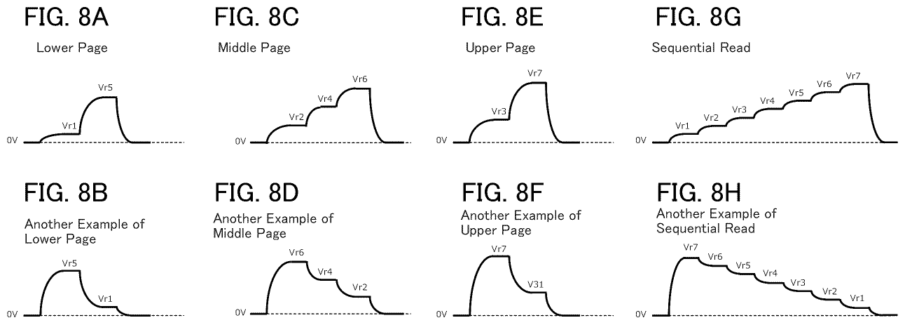

In the above, it has been explained that the read of the Lower page is performed in the order from the lowest read voltage, such as the order of the voltage Vr1 and the voltage Vr5. However, the reverse order from the highest read voltage, such as the order of the voltage Vr5 and the voltage Vr1, may be used. These respective states are illustrated in FIG. 8A and FIG. 8B.

When the read page is the Middle page, the control unit CTU performs a read at three read voltages. These voltages are the voltage Vr2, the voltage Vr4, and the voltage Vr6, which are the read voltages for the Middle page. The control unit CTU determines the value of the read data as “0” or “1” based on the result of the read at the threshold voltage of the voltage Vr2 (Step S112), the result of the read at the threshold voltage of the voltage Vr4 (Step S113), and the result of the read at the threshold voltage of the voltage Vr6 (Step S114) (Step S115). The control unit CTU transfers this one page of data from the sense amplifier SA to the data latch XDL (Step S116).

In the above, it has been explained that the read of the Middle page is performed in the order from the lowest read voltage, such as the order of the voltage Vr2, the voltage Vr4, and the voltage Vr6. However, the reverse order from the highest read voltage, such as the order of the voltage Vr6, the voltage Vr4, and the voltage Vr2, may be used. These respective states are illustrated in FIG. 8C and FIG. 8D.

When the read page is the Upper page, the control unit CTU performs a read at two read voltages. These voltages are the voltage Vr3 and the voltage Vr7, which are the read voltages for the Upper page. Then, the control unit CTU determines the value of the read data as “0” or “1” based on the result of the read at the threshold voltage of the voltage Vr3 (Step S122) and the result of the read at the threshold voltage of the voltage Vr7 (Step S123) (Step S124). The control unit CTU transfers this one page of data from the sense amplifier SA to the data latch XDL (Step S125).

In the above, it has been explained that the read of the Upper page is performed in the order from the lowest read voltage, such as the order of the voltage Vr3 and the voltage Vr7. However, the reverse order from the highest read voltage, such as the order of the voltage Vr7 and the voltage Vr3, may be used. These respective states are illustrated in FIG. 8E and FIG. 8F.

As a read sequence for another example, a sequential read illustrated in FIG. 8G or FIG. 8H may be performed. In this read method, an internal read is executed at all read voltages on the assumption that the Lower page, the Middle page, and the Upper page are output externally in succession. At this time, by controlling to sequentially increase the read voltage from the lowest read voltage (FIG. 8G) or sequentially decrease it from the highest voltage (FIG. 8H) to perform the internal read, a voltage change width for the word lines WL can be reduced, and the time taken for voltage transition can be shortened, resulting in the advantage of speeding up the read. The external output is possible after the read at the voltage Vr5, which is the read of the physical Lower page, is completed. Since a need arises to latch three pages of page data simultaneously, the respective three data latches ADL, BDL, XDL are used to evacuate the page read data.

### Write Operation

Next, programming is described. The control unit CTU of the non-volatile memory controls programming to the NAND flash memory cell array MCA based on the data coding illustrated in FIG. 6.

When a size of the memory cell MC as a three-dimensional memory cell is in a generation where miniaturization has not yet progressed and intervals between adjacent memory cells MC are wide, inter-adjacent memory cell interference is small. In this case, a method in which all bits are simultaneously programmed (to all pages simultaneously if each bit is assigned to a different page) is generally used. Based on all bits of data, which of the eight threshold distributions the data is located in is determined, and programming is performed to the determined region from the region S0 in the erase state. The inter-adjacent memory cell interference is described in detail.

### Method of Programming All Bits Simultaneously

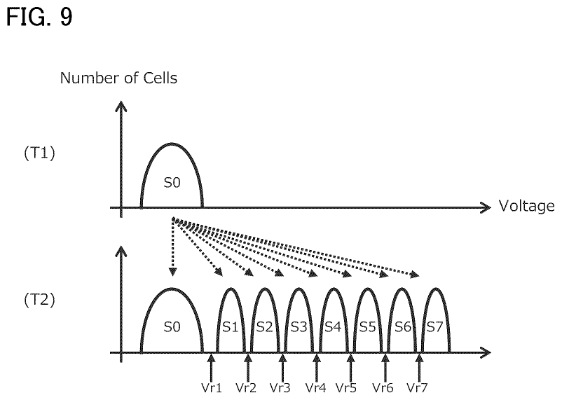

FIG. 9 illustrates the threshold distributions when all bits are simultaneously programmed. In FIG. 9, (T1) illustrates the threshold distribution in the erase state, which is an initial state before programming, and (T2) in FIG. 9 illustrates the threshold distributions after programming.

As illustrated in (T1) in FIG. 9, all memory cells MC of the NAND flash memory cell array MCA are in a state where their distributions are in the region S0 in the unwritten state (“erase” state). As illustrated in (T2) in FIG. 9, in programming, the control unit CTU of the non-volatile memory retains the distribution for each memory cell MC in the region S0 or moves the distribution for each memory cell MC to the regions S1 to S7 upper than the region S0 by injecting an electric charge according to the bit values to be written (stored) to the Lower page, the Middle page, and the Upper page.

Specifically, the control unit CTU does not inject an electric charge when the bit values to be written to the Lower page, the Middle page, and the Upper page are all “1”. The control unit CTU performs programming to move the threshold voltage to a higher side by injecting an electric charge when at least one of the bit values to be written to the Lower page, the Middle page, and the Upper page is “0”.

That is, when the bit values to be written to the Lower page, the Middle page, and the Upper page are “110”, the distribution of the threshold voltage is moved to the region S1. When the bit values to be written to the Lower page, the Middle page, and the Upper page are “100”, the distribution of the threshold voltage is moved to the region S2. When the bit values to be written to the Lower page, the Middle page, and the Upper page are “000”, the distribution of the threshold voltage is moved to the region S3. When the bit values to be written to the Lower page, the Middle page, and the Upper page are “010”, the distribution of the threshold voltage is moved to the region S4. When the bit values to be written to the Lower page, the Middle page, and the Upper page are “011”, the distribution of the threshold voltage is moved to the region S5. When the bit values to be written to the Lower page, the Middle page, and the Upper page are “001”, the distribution of the threshold voltage is moved to the region S6. When the bit values to be written to the Lower page, the Middle page, and the Upper page are “101”, the distribution of the threshold voltage is moved to the region S7.

Typically, programming is performed by applying one or a plurality of program voltage pulses to a word line WL. In the application of a plurality of program voltage pulses, the voltage value is increased in phases. After the application of each program voltage pulse, a read called verification is performed to confirm whether or not the threshold of a memory cell MC has moved beyond a threshold boundary level. By repeating these application and read, it is possible to move the threshold of the memory cell MC into a predetermined threshold distribution range.

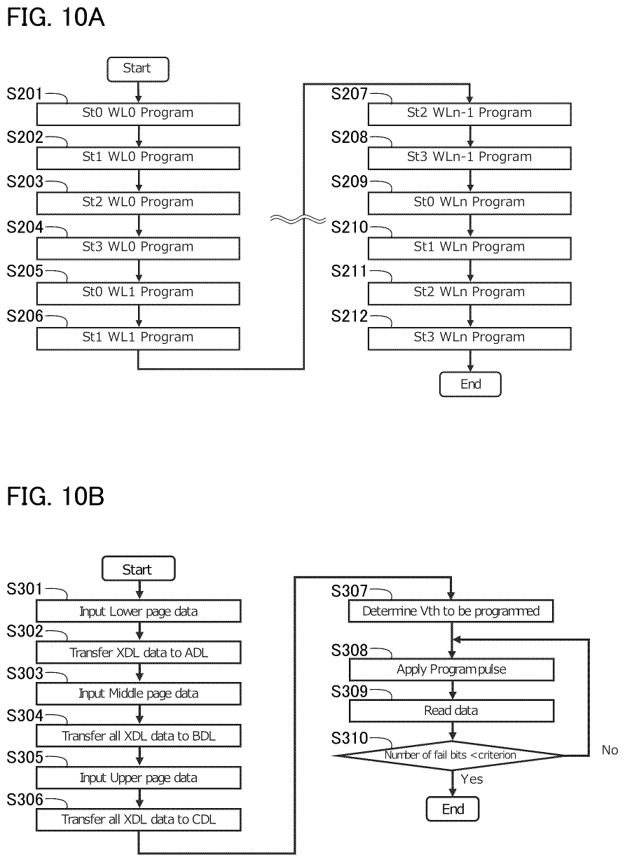

FIG. 10A is a flowchart illustrating an example of a programming order for one entire block BLK when all bits are simultaneously programmed. This flowchart illustrates an example of the programming order when the number of the strings St in the block BLK is four. Hereinafter, each of these four strings St is sometimes referred to as a string Stj using a string number j (j is an integer from 0 to 3). In addition, hereinafter, one block BLK has n+1 word lines WLi, expressed as word lines WL0 to WLn (n is a natural number), using a word line number i (i is an integer from 0 to n). Since the memory controller 30 proceeds with programming for the word lines WLi in consecutive order, it performs programming on a certain collection of word lines WLi (here, a block BLK) as a collection of program sequences.

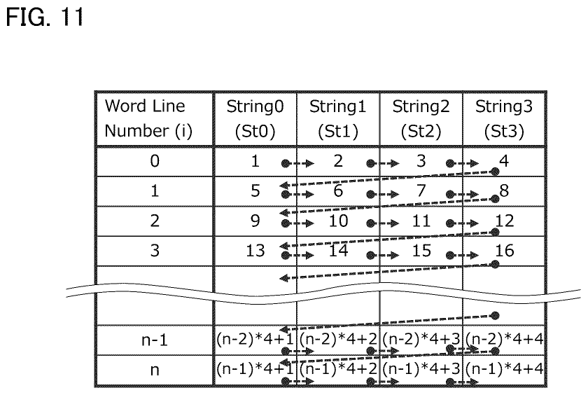

When a write is started, the control unit CTU (FIG. 1) selects the word lines WLi and the strings St in sequence in a predetermined order as illustrated in FIG. 10A and performs programming consecutively based on the instruction of the processor 33 (FIG. 2). The word lines WL are selected in order from the one with the smallest word line number i, as illustrated in FIG. 11. In addition, a plurality of physical memory cell groups MG corresponding to the same word line number i are selected in order from the one with the smallest string number j. Once programming for all the strings St0 to St3 (all the physical memory cell groups MG) corresponding to one word line WLi is completed, a word line WLi+1 corresponding to a next word line number i+1 is selected. In the following explanation, the operation of programming by the control unit CTU is based on the instructions from the processor 33, but to simplify the explanation, the description that it is based on the instructions from the processor 33 is omitted.

In the example illustrated in FIG. 10A, the control unit CTU first executes programming for the string St0 on the word line WL0 (Step S201). Next, the control unit CTU executes programming for the string St1 on the word line WL0 (Step S202). Next, the control unit CTU executes programming for the string St2 on the word line WL0 (Step S203). Next, the control unit CTU executes programming for the string St3 on the word line WL0 (Step S204). Next, the control unit CTU executes programming for the string St0 on the word line WL1 (Step S205). Next, the control unit CTU executes programming for the string St1 on the word line WL1 (Step S206). In the following, the control unit CTU similarly proceeds with the processing to the last word line in the block BLK in the order of the arrows in FIG. 10A (Steps S207 to S212).

While in FIG. 10A and FIG. 11, the case where the number of strings St in the block BLK is four has been described, the number of strings St in the block BLK may be three or less or five or more.

FIG. 10B is a sub-flowchart illustrating a write procedure for one word line WL when all bits are simultaneously programmed. In this programming, first, an input start command of Lower page data is input from the memory controller 30 (FIG. 2) to the NAND flash memory 40. Then, the Lower page data is input from the memory controller 30 to the data latch XDL of the NAND flash memory 40 (Step S301). When the control unit CTU (FIG. 1) detects that the data input from outside has finished, it transfers the data in the data latch XDL to the data latch ADL (Step S302).

Next, an input start command of Middle page data is input from the memory controller 30 to the NAND flash memory 40. Then, the Middle page data is input from the memory controller 30 to the data latch XDL of the NAND flash memory 40 (Step S303). When the control unit CTU detects that the data input from outside has finished, it transfers the data in the data latch XDL to the data latch BDL (Step S304).

Next, an input start command of Upper page data is input from the memory controller 30 to the NAND flash memory 40. Then, the Upper page data is input from the memory controller 30 to the data latch XDL of the NAND flash memory 40 (Step S305). When the control unit CTU detects that the data input from outside has finished, it transfers the data in the data latch XDL to the data latch CDL (Step S306).

Up to this point, the data for the Lower page, the Middle page, and the Upper page, which are necessary for programming to the word line WL, are transferred into the data latches ADL, BDL, CDL, respectively, and data preparation is completed. Furthermore, a program execution command is input from the memory controller 30 to the NAND flash memory 40, which enters a chip busy state. Then, Vth (threshold voltage) of each memory cell MC to be programmed to is determined based on the combinations of the data for the Lower page, the Middle page, and the Upper page input beforehand (Step S307). After this, three pages of data are written using the determined Vth.

In the data write, one to a plurality of program voltage pulses are applied (Step S308). As a first program voltage, a voltage with an initial value is applied. Second and subsequent program voltages may be increased from the voltage with the initial value by a predetermined voltage width. Then, a data read (verification) is performed to confirm whether or not the threshold of the memory cell MC has moved beyond a threshold boundary level (Step S309). A read level at this time is a predetermined level.

Furthermore, it is confirmed whether or not the number of data fail bits in each memory threshold region is less than a criterion (criterion for determining) (Step S310). When the number of data fail bits is greater than or equal to the criterion, the processing from the program pulse application to the criterion determination (Steps S308 to S310) is repeated. When the number of data fail bits is smaller than the criterion, it enters a chip ready state. Thus, by repeating the application, read, and confirmation, it is possible to move the threshold of the memory cell MC into a predetermined threshold distribution range.

The predetermined read level after the program voltage pulse application during the write may be slightly different from a read level after the write, preferably higher than the read level after the write. This is to make room for threshold determination in the read after the write. Then, when the numbers of data fail bits in all the threshold regions are smaller than the criterion, it enters the chip ready state.

### Inter-Adjacent Memory Cell Interference

Here, the inter-adjacent memory cell interference is described. In first inter-adjacent memory cell interference, the electric charge accumulated in the electric charge accumulating layer 336 (FIG. 4B) of one memory cell MC disturbs an electric field of an adjacent memory cell MC, consequently providing noise that varies the threshold when a read is performed on the adjacent memory cell MC. After programming and verification are performed under a certain electric field condition and the programming is completed, the adjacent memory cell MC is programmed with a different electric charge. Then, the threshold voltage varies to a higher side due to an influence of its electric field, causing read accuracy to deteriorate. Typically, after programming is completed, when programming to a high threshold voltage distribution is performed on a memory cell MC adjacent to a memory cell MC located in a low threshold voltage distribution, the threshold voltage increases after the programming to the adjacent memory cell MC is completed. This inter-adjacent memory cell interference becomes more pronounced as a manufacturing technique of memory devices is miniaturized, and intervals between memory cells decrease. Additionally, this inter-adjacent memory cell interference occurs mainly between adjacent memory cells MC connected to different word lines on the same bit line BL.

In addition, second inter-adjacent memory cell interference caused by another physical phenomenon different from this is electric charge coupling between adjacent cells. When there is a difference between an amount of electric charge accumulated in the electric charge accumulating layer 336 of one memory cell MC and an amount of electric charge accumulated in the electric charge accumulating layer 336 of a memory cell MC adjacent to the one memory cell MC, that is, there is a difference in the threshold voltage, the electric charges are gradually coupled and neutralized in a boundary region between the adjacent cells over time after the programming. This creates noise that varies the threshold, causing the read accuracy to deteriorate. Typically, when a memory cell MC located in a high threshold voltage distribution and a memory cell MC located in a low threshold voltage distribution are adjacent, the threshold voltage of the memory cell MC located in the high threshold voltage distribution decreases, and the threshold voltage of the memory cell MC located in the low threshold voltage distribution increases at the same time. In particular, in the memory cell MC located in the high threshold voltage distribution, a decrease in the threshold voltage is especially large because there is also a decrease in the threshold voltage due to another factor, which is a time-course leakage of the electric charge injected in the programming. This inter-adjacent memory cell interference also becomes more pronounced as the manufacturing technique of memory devices is miniaturized, and the intervals between memory cells decrease. Similarly, this inter-adjacent memory cell interference occurs mainly between adjacent memory cells MC connected to different word lines on the same bit line BL.

### Foggy-Fine Programming

The first inter-adjacent memory cell interference can be mitigated by reducing a difference in electric field conditions of the memory cells MC between the time of programming and verification and the time of the read after the adjacent memory cell MC is programmed. As one method of reducing the inter-adjacent memory cell interference between adjacent memory cells MC connected to different word lines WL on the same bit line BL, a programming method (Foggy-Fine programming) in which a small amount of electric charge is gradually injected into the electric charge accumulating layer 336 of the memory cells MC using a plurality of programming stages, for example, two programming stages (hereinafter, referred to simply as stages in some cases) is employed. In this Foggy-Fine programming, after a write is performed on a memory cell MC in a first stage (Foggy stage), a write is performed on an adjacent cell. Then, back to the first memory cell MC, a write is performed in a second stage (Fine stage). Each stage in this case is an execution unit of programming, and the programming for the memory cells MC corresponding to one word line WLi is completed by executing the two programming stages.

In both the first-stage programming and the second-stage programming, programming is executed using eight threshold regions. The threshold distributions of the threshold regions at the end of the first-stage programming have wider widths than the threshold distributions of the threshold regions in final data coding. That is, a Foggy (rough) write is performed in the Foggy stage. In this Foggy-stage programming, input data for all three pages are required. Since the threshold distributions after the Foggy-stage programming are in an intermediate state in which the adjacent distributions overlap with one another, a data read cannot be performed. In the programming in the Fine stage that is the second stage, the threshold regions after the Foggy-stage programming are moved to the threshold regions in the final data coding. That is, a Fine write is performed in the Fine stage. In this Fine-stage programming, input data for all three pages are also required. Since the threshold distributions after the Fine-stage programming are in a final state in which the adjacent distributions are separated, a data read can be performed after the Fine-stage programming.

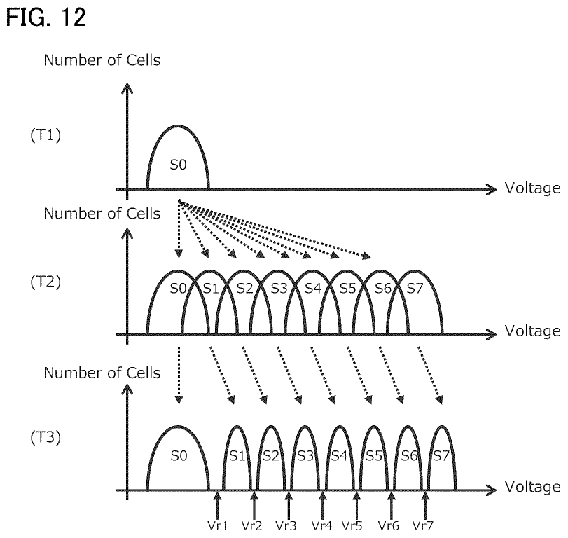

When large inter-adjacent memory cell interference is expected, programming is performed according to the Foggy-Fine programming as the program sequence. FIG. 12 is a drawing illustrating the threshold distributions after programming in the Foggy-Fine programming. In FIG. 12, (T1) illustrates the threshold distribution in the erase state, which is an initial state before programming. In FIG. 12, (T2) illustrates the threshold distributions after the first-stage programming (Foggy programming). In FIG. 12, (T3) illustrates the threshold distributions after the second-stage programming (Fine programming).

As illustrated in (T1) in FIG. 12, the threshold voltages of all memory cells MC of the NAND flash memory cell array MCA are in the region S0 in the unwritten state (“erase” state).

As illustrated in (T2) in FIG. 12, in the first-stage programming, the control unit CTU of the NAND flash memory 40 retains the threshold distribution for each memory cell MC in the region S0 or moves the threshold distribution for each memory cell MC to the regions S1 to S7 upper than the region S0 by injecting an electric charge according to the bit values to be written (stored) to the Lower page, the Middle page, and the Upper page. A mapping relationship between the bit values to be written and the threshold regions is as described above. Here, programming is performed roughly by broadening the widths of the threshold distributions in the regions S1 to S7 so that the threshold voltages are slightly lower.

As a result, the memory cells MC are programmed at an eight-value level with the data for the Lower page, the Middle page, and the Upper page, but the data cannot be read because the threshold distributions are wide in width and overlap with other threshold distributions adjacent to one another. However, since it is not necessary to shape the threshold distributions after the first-stage programming in a thin manner, high-speed programming is possible.

In addition, as illustrated in (T3) in FIG. 12, the data for all pages of the Lower page, the Middle page, and the Upper page are also required for a data write in the second-stage programming. Then, after the second-stage programming, the control unit CTU of the NAND flash memory 40 performs programming so that the threshold distributions are finally separated into eight threshold regions. Consequently, all the page data can be read. In the second-stage programming, the larger variation widths in the threshold voltages of the memory cells MC from the end of the first-stage programming, the greater the first inter-adjacent cell interference. Therefore, when the threshold voltages in the first stage change to the threshold voltages in the second stage, the variation widths preferably become smaller.

Typically, a write (programming) to a memory cell MC is performed by applying one or a plurality of program voltage pulses to the corresponding word line WL. After each program voltage pulse is applied, a read is performed to confirm whether or not the threshold voltage of the memory cell MC has moved beyond a threshold boundary level. By repeating these application and read, it is possible to move the threshold voltage of the memory cell MC into the predetermined regions S1 to S7. From the data for all pages of the write targets, the threshold voltage of the corresponding memory cell MC is determined, and the voltage value of the plurality of program pulses is increased little by little to perform the write so that the determined threshold voltage is reached. The memory cell MC that has reached the target threshold voltage is excluded from the write targets.

In addition, the control unit CTU does not consecutively execute the first-stage programming and the second-stage programming to a plurality of physical memory cell groups MG corresponding to one word line WLi, but executes programming across a plurality of word lines WLi in a non-consecutive order to reduce an effect of the inter-adjacent memory cell interference.

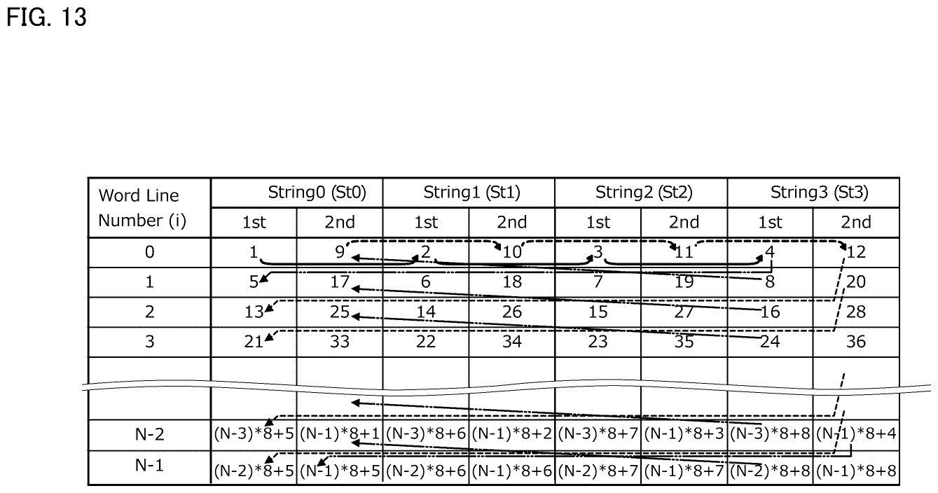

FIG. 13 is a drawing illustrating a programming order of the Foggy-Fine programming. The example illustrated in FIG. 13 indicates an example of the programming order in the NAND flash memory 40 where four strings St0 to St3 are connected to each word line WLi in each block BLK. In the example illustrated in FIG. 13, programming is performed in two programming stages to reduce the effect of the first inter-adjacent memory cell interference.

When a write is started, the control unit CTU (FIG. 1) goes through each programming stage while crossing the word lines WLi in a predetermined non-consecutive order. That is, the first-stage programming and the second-stage programming for the same word line WL are not executed consecutively. After the first-stage programming is performed on all the physical memory cell groups MG corresponding to a certain word line WLi, the second-stage programming is performed on all the physical memory cell groups MG corresponding to an immediately previous word line WLi−1. After programming for the certain word line WLi is completed up to the second stage, the first-stage programming and the second-stage programming are consecutively performed on an adjacent word line WLi+1, resulting in large amounts of variation in the threshold voltages in a plurality of memory cells MC corresponding to the word line WLi. When the amounts of variation in the threshold voltages on the adjacent word line WLi+1 are large, the inter-adjacent memory cell interference between the word line WLi and the word line WLi+1 increases.

In order to decrease the inter-adjacent memory cell interference between the word lines WL, it is effective to reduce the variations in the threshold voltages of the plurality of memory cells MC corresponding to the word line WLi due to the programming for the adjacent word line WLi+1 after programming for the word line WLi is completed up to the second stage. In the order in FIG. 13, after programming for a certain word line WLi is completed up to the second stage, the programming stage for the adjacent word line WLi+1 is only the second stage. Accordingly, the variations in the threshold voltages of the plurality of memory cells MC corresponding to the word line WLi can be reduced appropriately.

While in FIG. 13, the case where the number of strings St in the block BLK is four has been described, the number of strings St in the block BLK may be three or less or five or more.

For example, in the example illustrated in FIG. 4A, an adjacent word line WL relative to a k-th (k is a natural number) word line WL counting from one side among a plurality of word lines WL arranged in the Z-direction is a k−1-th word line WL or a k+1-th word line WL counting from one side.

### Rewrite Operation

Next, a rewrite operation is described. In the first embodiment, a countermeasure against the first inter-adjacent memory cell interference is taken by the Foggy-Fine programming, and further, a countermeasure against the second inter-adjacent memory cell interference is taken by a rewrite operation.

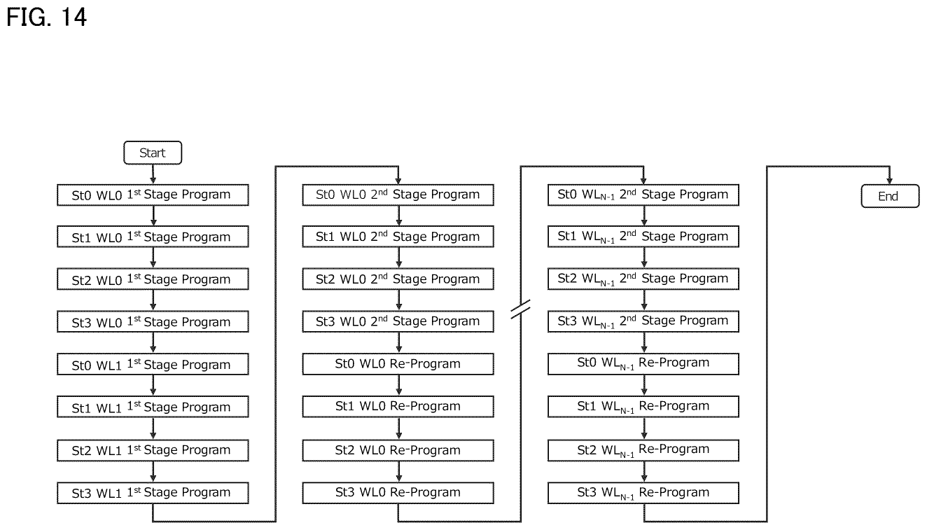

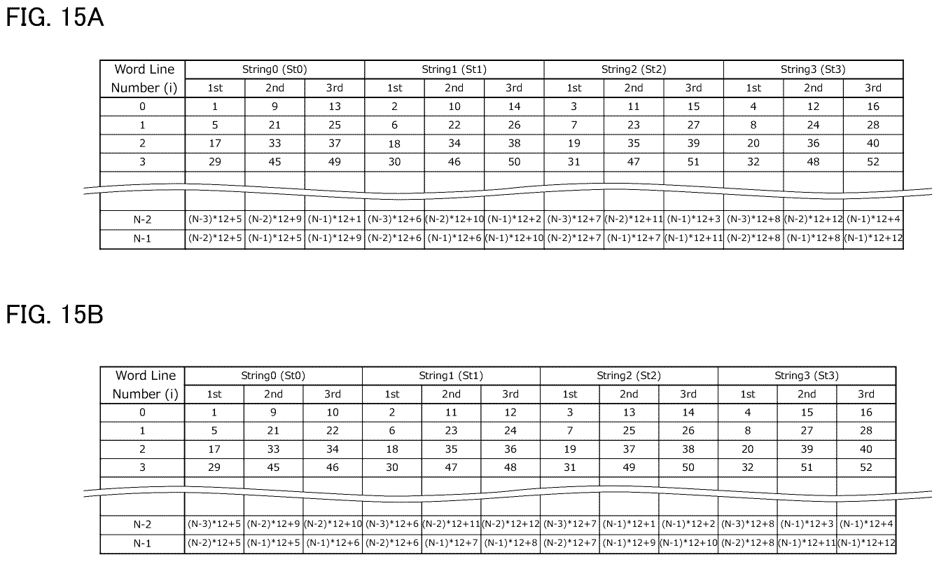

FIG. 14 is a flowchart illustrating an example of the programming order for one entire block BLK in the first embodiment. FIGS. 15A and 15B are drawings illustrating examples of the order of selecting the word lines WL in programming in the first embodiment.

When a write is started, the control unit CTU (FIG. 1) selects the word lines WL0 to WLn and the strings St0 to St3 in sequence in a predetermined order as illustrated in FIG. 14 and performs programming consecutively based on the instruction of the processor 33 (FIG. 2). The word lines WL are selected in order from the one with the smallest word line number i, as illustrated in FIGS. 15A and 15B. In addition, a plurality of physical memory cell groups MG corresponding to the same word line number i are selected in order from the one with the smallest string number j.

In the example of FIG. 15A, after the first-stage programming is performed on all the strings St0 to St3 (all the physical memory cell groups MG) corresponding to one word line WLi, the second-stage programming is performed on all the physical memory cell groups MG corresponding to the immediately previous word line WLi−1. Furthermore, third-stage programming is performed on all the physical memory cell groups MG corresponding to the word line WLi−1.

In the example of FIG. 15B, after the first-stage programming is performed on all the strings St0 to St3 (all the physical memory cell groups MG) corresponding to one word line WLi, the second-stage programming and the third-stage programming are performed in sequence on all the physical memory cell groups MG corresponding to the immediately previous word line WLi−1.

There are three programming stages. The first-stage and second-stage programming is the same as the Foggy-Fine programming in the conventional example, and the third-stage programming (rewrite) is added to them. After the second-stage programming is completed for all the strings St0 to St3 in the word line number i, back to the first string number 0 in the same word line number i, the third-stage programming is executed in order from the one with the smallest string number j.

While in FIG. 14 and FIG. 15A, the case where the number of strings St in the block BLK is four has been described, the number of strings St in the block BLK may be three or less or five or more. Since the write procedure for one word line WLi is basically similar to the description in FIG. 10B, it is omitted.

FIG. 15B illustrates an example of executing the third-stage programming for the word line WLi immediately after the second-stage programming for the word line WLi as a modification of FIG. 15A. The example illustrated in FIG. 15B has the advantage of simplifying the program sequence compared to the example illustrated in FIG. 15A in that the third-stage programming is executed without changing a word line address. However, the rewrite is performed when an initial electric charge leakage is not yet sufficient due to the timing immediately after the second-stage programming, and before the second-stage programming is performed for the next adjacent word line WLi+1. Therefore, the corresponding word line WLi is not affected by the inter-adjacent cell interference until the final state. That is, there is a disadvantage that a desired threshold increase width may not be achieved by performing the rewrite in a state where the threshold distributions are not yet determined in a final form. Specifically, for example, by performing the rewrite on a memory cell MC where the initial electric charge leakage is not yet sufficient, there is a risk that the threshold voltage after the rewrite becomes higher than planned and reaches the region of the distribution adjacent to a high voltage side. This is referred to as an excessive write (over-programming) and is one of the causes of data errors in the NAND flash memory 40.

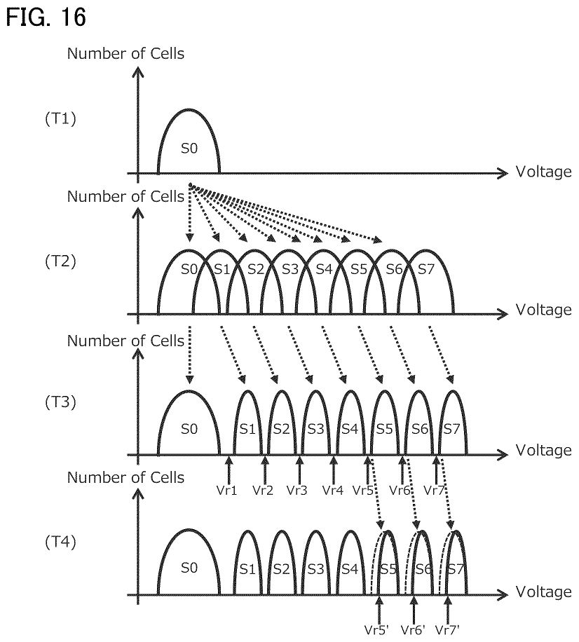

FIG. 16 is a drawing illustrating the threshold distributions after programming in the first embodiment. In FIG. 16, (T1) illustrates the threshold distribution in the erase state, which is an initial state before programming. In FIG. 16, (T2) illustrates the threshold distributions after the first-stage programming (Foggy programming). In FIG. 16, (T3) illustrates the threshold distributions after the second-stage programming (Fine programming). In FIG. 16, (T4) illustrates the threshold distributions after the third-stage programming (reprogramming).

As illustrated in (T1) in FIG. 16, the threshold voltages of all memory cells MC of the NAND flash memory cell array MCA are in the region S0 in the unwritten state (“erase” state).

As illustrated in (T2) in FIG. 16, in the first-stage programming, the control unit CTU of the NAND flash memory 40 retains the threshold distribution for each memory cell MC in the region S0 or moves the threshold distribution for each memory cell MC to the threshold regions S1 to S7 upper than the region S0 by injecting an electric charge according to the bit values to be written (stored) to the Lower page, the Middle page, and the Upper page. A mapping relationship between the bit values to be written and the threshold regions is as described above. Here, programming is performed roughly by broadening the widths of the threshold distributions in the regions S1 to S7 so that the threshold voltages are slightly lower.

As a result, the memory cells MC are programmed at an eight-value level with the data for the Lower page, the Middle page, and the Upper page, but the data cannot be read because the threshold distributions are wide in width and overlap with other threshold distributions adjacent to one another. However, since it is not necessary to shape the threshold distributions after the first-stage programming in a thin manner, high-speed programming is possible.

In addition, as illustrated in (T3) in FIG. 16, the data for all pages of the Lower page, the Middle page, and the Upper page are also required for a data write in the second-stage programming. Then, after the second-stage programming, the control unit CTU of the NAND flash memory 40 performs programming so that the threshold distributions are finally separated into eight threshold regions. Consequently, all the page data can be read. In the second-stage programming, the larger the variation widths in the threshold voltages of the memory cells MC from the end of the first-stage programming, the greater the first inter-adjacent cell interference. Therefore, when the threshold voltages in the first stage change to the threshold voltages in the second stage, the variation widths preferably become smaller.

For example, a write (programming) to a memory cell MC is performed by applying one or a plurality of program voltage pulses to the corresponding word line WL. After each program voltage pulse is applied, a read is performed to confirm whether or not the threshold of the memory cell MC has moved beyond a threshold boundary level. By repeating these application and read, it is possible to move the threshold distribution of the memory cell MC into the predetermined regions S1 to S7. From the data for all pages of the write targets, the threshold voltage of the corresponding memory cell MC is determined, and the voltage value of the plurality of program pulses is increased little by little to perform the write so that the determined threshold voltage is reached. The memory cell MC that has reached the target threshold voltage is excluded from the write targets.

As illustrated in (T4) in FIG. 16, in the third-stage programming, the control unit CTU of the NAND flash memory 40 performs a “weak” write on only the memory cells MC in the region S5 to the region S7 as the targets, according to the bit values to be written (stored) to the Lower page, the Middle page, and the Upper page, by adjusting a magnitude of the program voltage so as to decrease the threshold increase width by the application of one program voltage pulse (setting the threshold increase width to be lower than that in the second-stage programming). This increases only the threshold voltages of the memory cells MC located on the lower side of the distributions without increasing the threshold voltages of those located on the higher side of the distributions.

In the third-stage programming, verification may be performed, or verification may be omitted. When the verification is performed, verify voltages are set to be equal to verify voltages (voltages Vr5, Vr6, Vr7) in the second-stage programming or to be voltages Vr5′, Vr6′, Vr7′, which are higher than the voltages Vr5, Vr6, Vr7.

In the rewrite (third-stage programming) to the region S5 to the region S7, the memory cells MC to be the write targets are determined according to the write data of adjacent cells.

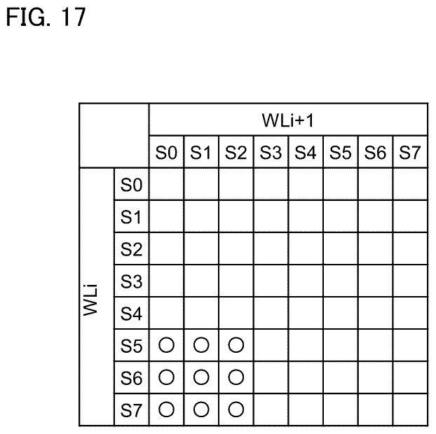

FIG. 17 illustrates an example of combinations of the threshold regions between the target cells and the adjacent cells that are the write targets for the third-stage programming in the first embodiment. In FIG. 17, parts marked with “○” correspond to the memory cells MC as the write targets. The memory cells MC as the write targets are memory cells MC that are subject to the write to the regions S5 to S7 in the third-stage programming for the word line WLi and whose adjacent cells on the word line WLi+1 are subject to the write to the regions S0 to S2.

In FIG. 17, the memory cells MC in other combinations without the mark are not the write targets in the third-stage programming. The combinations illustrated in FIG. 17 are an example, and the combinations to be the write targets may be enlarged or reduced depending on a strength of the inter-adjacent cell interference and the like. In addition, at least one of the magnitude and a pulse width (application time) of the program voltage in the third stage may be individually set for the memory cells MC corresponding to the respective regions S5 to S7. For example, the program voltage in the third stage (a voltage with an initial value when verification is performed) may be greater than the program voltage in the first stage (a voltage with an initial value when verification is performed). For example, the program voltage in the third stage (the voltage with an initial value when verification is performed) may be lower than the program voltage in the second stage (a voltage with an initial value when verification is performed). For example, the application time of the program voltage in the third stage may be longer than the application time of the program voltage in the first stage. For example, the application time of the program voltage in the third stage may be shorter than the application time of the program voltage in the second stage.

The advantage of limiting the memory cells MC as rewrite targets to those with large inter-adjacent cell interference is as follows. Performing a write on a NAND flash memory cell involves applying a program voltage to the word line WLi and injecting an electric charge into the electric charge accumulating layer 336 (FIG. 4B), and the injected electric charge amount is typically determined by the program voltage. However, since the respective memory cells MC have individual differences in shape and characteristics, a variation in the injected electric charge amount occurs between the memory cells MC connected to the same word line WLi and subject to the write simultaneously. As a result, threshold voltage widths that increase with one program pulse vary. Therefore, when a write is simultaneously performed on a large number of memory cells MC, a small number of memory cells MC may cause an unexpected large threshold voltage increase with a certain probability, and further, some of them may reach the region of the distribution adjacent to the high voltage side. This is referred to as an excessive write (over-programming) and is one of the causes of data errors in the NAND flash memory 40. Limiting the memory cells MC as the rewrite targets only to those that are necessary to reduce the number of memories has an effect of reducing the occurrence of the excessive write.

For example, write data stored in a data buffer (RAM 31) of the memory controller 30 is used to determine the combinations of the distribution with the adjacent cells to be the write targets for the third-stage programming illustrated in FIG. 17. For example, when a write distribution for the word line WLi is in the region S5 and a write distribution for the word line WLi+1 is in the region S0 it is determined that the bit values to be written to the respective pages of the word line WLi are “011”, and the bit values to be written to the respective pages of the adjacent word line WLi+1 are “111”.

When the memory controller 30 performs programming in the order illustrated in FIG. 15A or FIG. 15B, the data buffer (RAM 31) must always store the page data for three consecutive word lines WL because the order goes back and forth between the word line numbers i, including a case where one word line number i is skipped. That is, the third-stage programming for the word line WLi is executed immediately after the second-stage programming for the word line WLi and between the first-stage programming and the second-stage programming for the word line WLi+1. Therefore, the page data for the word line WLi and the word line WLi+1 are both present in the data buffer (RAM 31) of the memory controller 30, and computing using these pieces of data is easy.

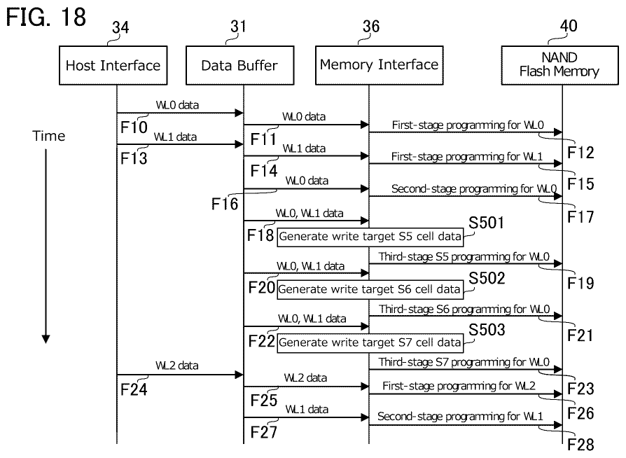

FIG. 18 illustrates a control flow of write data in the first embodiment. Here, it is assumed that the memory interface 36 in the memory controller 30 performs determination computing of the write-target memory cells MC for the third-stage programming. In the third-stage programming, a write control is performed for each threshold region.

First, write data for the word line WL0 is sent from the host interface 34 to the data buffer (RAM 31) (Flow F10), and it is sent from the data buffer (RAM 31) to the memory interface 36 (Flow F11). The memory interface 36 sends this write data for the word line WL0 to the NAND flash memory 40 (Flow F12), and the first-stage programming for the word line WL0 is executed in the NAND flash memory 40.

Next, write data for the word line WL1 is sent from the host interface 34 to the data buffer (RAM 31) (Flow F13), and it is sent from the data buffer (RAM 31) to the memory interface 36 (Flow F14). The memory interface 36 sends this write data for the word line WL1 to the NAND flash memory 40 (Flow F15), and the first-stage programming for the word line WL1 is executed in the NAND flash memory 40.

Next, the write data for the word line WL0 is sent from the data buffer (RAM 31) to the memory interface 36 (Flow F16). The memory interface 36 sends this write data for the word line WL0 to the NAND flash memory 40 (Flow F17), and the second-stage programming for the word line WL0 is executed in the NAND flash memory 40.

Next, the write data for the word lines WL0, WL1 are sent from the data buffer (RAM 31) to the memory interface 36 (Flow F18).

Next, for example, in the third-stage region S5 programming for the word line WL0, one page of data (rewrite data) is generated according to determination conditions illustrated in FIG. 17. In the one page of data, bits, where the write data for the word line WL0 and the write data for the word line WL1 correspond respectively to the region S5 and the regions S0 to S2, are write bits, and other bits are non-write bits (Step S501).

Next, the memory interface 36 sends this one page of data to the NAND flash memory 40 (Flow F19), and a one-page rewrite is executed for the word line WL0 in the NAND flash memory 40.

Next, the write data for the word lines WL0, WL1 are sent from the data buffer (RAM 31) to the memory interface 36 (Flow F20).

Next, in the third-stage region S6 programming for the word line WL0, one page of data (rewrite data) is generated according to the determination conditions illustrated in FIG. 17. In the one page of data, bits, where the write data for the word line WL0 and the write data for the word line WL1 correspond respectively to the region S6 and the regions S0 to S2, are write bits, and other bits are non-write bits (Step S502).

Next, the memory interface 36 sends this one page of data to the NAND flash memory 40 (Flow F21), and a one-page rewrite is executed for the word line WL0 in the NAND flash memory 40.

Next, the write data for the word lines WL0, WL1 are sent from the data buffer (RAM 31) to the memory interface 36 (Flow F22).

Next, in the third-stage region S7 programming for the word line WL0, one page of data (rewrite data) is generated according to the determination conditions illustrated in FIG. 17. In the one page of data, bits, where the write data for the word line WL0 and the write data for the word line WL1 correspond respectively to the region S7 and the regions S0 to S2, are write bits, and other bits are non-write bits (Step S503).

Next, the memory interface 36 sends this one page of data to the NAND flash memory 40 (Flow F23), and a one-page rewrite is executed for the word line WL0 in the NAND flash memory 40.

Hereinafter, similarly for the word lines WL2 and beyond (flows F24 to F28 and beyond), write data is sent to the data buffer (RAM 31), and one page of data for the third-stage programming is generated in the memory interface 36.

In the example illustrated in FIG. 18, the procedure for rewriting one page of write data for one rewrite-target distribution after another is illustrated, but all the rewrite-target cells may be lumped together. For example, it is possible to specify the bit values to be written to the pages of “011” for the cells corresponding to the threshold region S5 of the rewrite target conditions illustrated in FIG. 17, the bit values to be written to the pages of “001” for the cells corresponding to the region S6, the bit values to be written to the pages of “101” for the cells corresponding to the threshold region S7, and the bit values to be written to the pages of “111”, that is, erase distribution data to treat as non-write cells, for the other cells. Such page data can be sent from the memory interface 36 to the NAND flash memory 40 as rewrite data to execute a write.

### Effects

With this embodiment, in the memory cells MC whose data retention deteriorates depending on adjacent cell patterns, a margin of threshold downshift of the data retention can be increased to provide a highly reliable memory system 10.

In addition, in this embodiment, since the selection of the memory cells MC subject to a rewrite (generation of rewrite data) is performed by computing from write data, there is no need to perform a read operation from the memory cells MC corresponding to the word line WLi+1. Therefore, since the time required for the read operation, data transfer between a memory chip and the memory controller 30, ECC decoding, and the like is unnecessary, the selection of the memory cells MC subject to a rewrite is executable at high speed.

Note that an additional write operation according to this embodiment can be realized without the need for an additional data buffer (RAM 31) when the Foggy-Fine programming is employed as the program sequence. This is because the write data in the data buffer (RAM 31) is used to perform the determination computing of the write-target cells for the third-stage programming.

### Modification of First Embodiment

While the case of 3 bits/Cell has been described as an example in this embodiment, cases of other multi-value numbers (such as 2 bits/Cell, 4 bits/Cell, and 5 bits/Cell) are similarly applicable.

In addition, while the case with the Foggy-Fine programming as the program sequence has been described as an example, cases with other multi-stage programming are similarly applicable. Furthermore, even a program sequence in which all bits are simultaneously programmed is similarly applicable by storing the write data for a plurality of adjacent word lines WL in a controller buffer.

Additionally, the example of storing the write data corresponding to three word lines WL, which are consecutive in the write order, in the data buffer (RAM 31) of the memory controller 30 has been illustrated in this embodiment. However, this write data may be stored in, for example, a data buffer contained in the NAND flash memory 40.

In this embodiment, the target cells for the rewrite operation are determined based on the data of a plurality of memory cells MC corresponding to the selected word line WLi and the data of a plurality of memory cells MC corresponding to the adjacent word line WLi+1. However, for example, the target cells for the rewrite operation may be determined based on the data of a plurality of memory cells MC corresponding to the adjacent word line WLi−1 in addition to these pieces of data.

### Second Embodiment

A second embodiment is an addition to the countermeasure against the first inter-adjacent memory cell interference by the Foggy-Fine programming. However, since its means has many parts in common with the first embodiment, it is described while omitting the parts as appropriate.

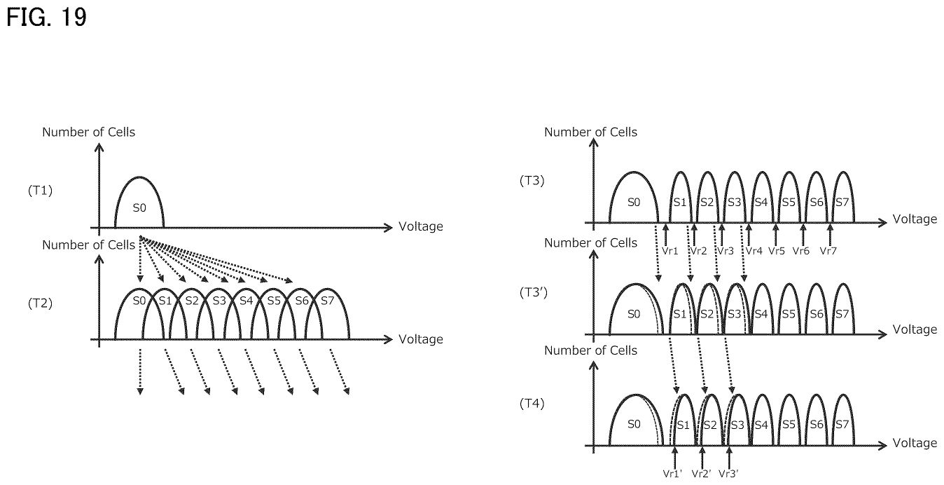

FIG. 19 is a drawing illustrating threshold distributions after programming in the second embodiment. In FIG. 19, (T1) illustrates the threshold distribution in the erase state, which is an initial state before programming. In FIG. 19, (T2) illustrates the threshold distributions after first-stage programming (Foggy programming). In FIG. 19, (T3) illustrates the threshold distributions after second-stage programming (Fine programming). The descriptions of (T1) through (T3) in FIG. 19 are the same as those in FIG. 16 and are omitted.

In FIG. 19, (T3′) illustrates the threshold distributions after the first-stage programming (Foggy programming) for a next adjacent word line WL. For the memory cells MC in low threshold regions, such as the regions S0 to S3, the higher the voltage of the threshold region after a write to the memory cells MC (adjacent cells) corresponding to the adjacent word line WL, the more the threshold voltage varies to the high voltage side due to the first inter-adjacent cell interference. As a result, the distributions of the low threshold regions, such as the regions S0 to S3, increase in width toward an upper side. In view of this, after the first-stage programming for the next adjacent word line WL, especially, the distributions of the low threshold regions have narrower intervals with respect to the distributions of the neighboring threshold regions, and data errors are prone to occur during a read.

In FIG. 19, (T4) illustrates the threshold regions after third-stage programming (reprogramming). As illustrated in (T4) in FIG. 19, in the third-stage programming, the control unit CTU of the NAND flash memory 40 performs a “weak” write on only the memory cells MC in the threshold region S1 to the region S3 as the targets, according to the bit values to be written (stored) to the Lower page, the Middle page, and the Upper page, by adjusting the magnitude of the program voltage so as to decrease the threshold increase width by the application of one program voltage pulse (setting the threshold increase width to be lower than that in the second-stage programming). This increases only the threshold voltages of the memory cells MC located on the lower side of the distributions without increasing the threshold voltages of those located on the higher side of the distributions.

In this third-stage programming, verification may be performed, or verification may be omitted. When the verification is performed, verify voltages are set to be equal to or higher than the verify voltages in the second-stage programming.

In the rewrite to the threshold region S1 to the region S3, the memory cells MC to be the write targets are determined according to the write data of adjacent cells.

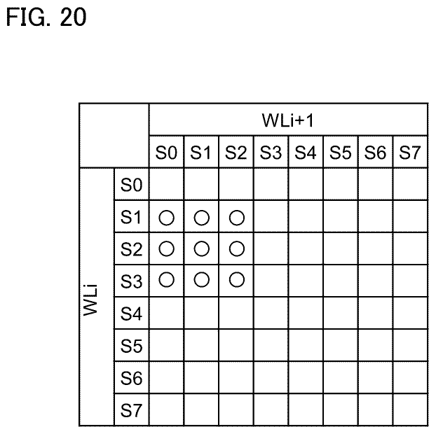

FIG. 20 illustrates an example of combinations of the threshold regions between the target cells and the adjacent cells that are the write targets for the third-stage programming in the second embodiment. In FIG. 20, the memory cells MC as the write targets are memory cells MC in the combinations marked with “○”, which have threshold voltages in the region S1 to the region S3 in the third-stage programming for the word line WLi and whose adjacent memory cells MC on the word line WLi+1 have threshold voltages in the region S0 to the region S2.

In FIG. 20, the memory cells MC in other combinations without the mark are not the write targets. The combinations illustrated in FIG. 20 are an example, and the combinations to be the write targets may be enlarged or reduced depending on the strength of the inter-adjacent cell interference and the like. In addition, at least one of the magnitude and the pulse width (application time) of the program voltage in the third stage may be individually set for the memory cells MC corresponding to the respective regions S1 to S3. For example, the program voltage in the third stage (a voltage with an initial value when verification is performed) may be greater than the program voltage in the first stage (a voltage with an initial value when verification is performed). For example, the program voltage in the third stage (the voltage with an initial value when verification is performed) may be lower than the program voltage in the second stage (a voltage with an initial value when verification is performed). For example, the application time of the program voltage in the third stage may be longer than the application time of the program voltage in the first stage. For example, the application time of the program voltage in the third stage may be shorter than the application time of the program voltage in the second stage.

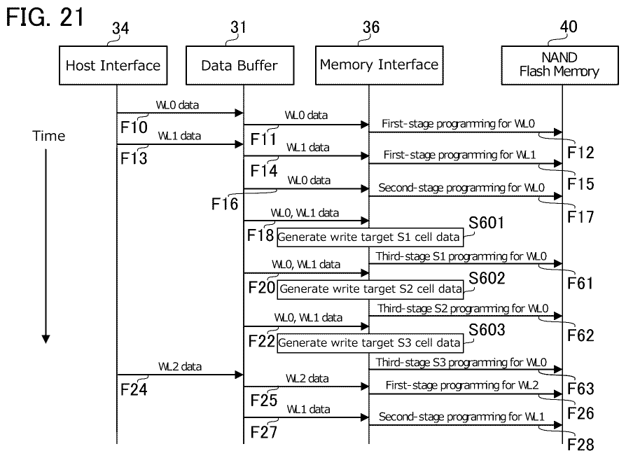

FIG. 21 illustrates a control flow of write data in the second embodiment. In the third-stage programming, a write control is performed for each threshold region.

The control flow illustrated in FIG. 21 is basically similar to the control flow illustrated in FIG. 18. However, in the control flow illustrated in FIG. 21, Steps S601, S602, and S603 are performed instead of Steps S501, S502, and S503, and Flows F61, F62, and F63 are performed instead of Flows F19, F21, and F23.

For example, in the third-stage region S1 programming for the word line WL0, one page of data (rewrite data) is generated according to determination conditions illustrated in FIG. 20. In the one page of data, bits, where the write data for the word line WL0 and the write data for the word line WL1 correspond respectively to the region S1 and the regions S0 to S2, are write bits, and other bits are non-write bits (Step S601).

Next, the memory interface 36 sends this one page of data to the NAND flash memory 40 (Flow F61), and a one-page rewrite is executed for the word line WL0 in the NAND flash memory 40.

Next, in the third-stage region S2 programming for the word line WL0, one page of data (rewrite data) is generated according to the determination conditions illustrated in FIG. 20. In the one page of data, bits, where the write data for the word line WL0 and the write data for the word line WL1 correspond respectively to the region S2 and the regions S0 to S2, are write bits, and other bits are non-write bits (Step S602).

Next, the memory interface 36 sends this one page of data to the NAND flash memory 40 (Flow F62), and a one-page rewrite is executed for the word line WL0 in the NAND flash memory 40.

Next, in the third-stage region S3 programming for the word line WL0, one page of data (rewrite data) is generated according to the determination conditions illustrated in FIG. 20. In the one page of data, bits, where the write data for the word line WL0 and the write data for the word line WL1 correspond respectively to the region S3 and the regions S0 to S2, are write bits, and other bits are non-write bits (Step S603).

Next, the memory interface 36 sends this one page of data to the NAND flash memory 40 (Flow F63), and a one-page rewrite is executed for the word line WL0 in the NAND flash memory 40.

In the example illustrated in FIG. 21, the procedure for rewriting one page of write data for one rewrite-target distribution after another is illustrated, but all the rewrite-target cells may be lumped together. For example, it is possible to specify the bit values to be written to the pages of “110” for the cells corresponding to the threshold region S1 of the rewrite target conditions illustrated in FIG. 20, the bit values to be written to the pages of “100” for the cells corresponding to the region S2, the bit values to be written to the pages of “000” for the cells corresponding to the region S3, and the bit values to be written to the pages of “111”, that is, erase distribution data to treat as non-write cells, for the other cells. Such page data can be sent from the memory interface 36 to the NAND flash memory 40 as rewrite data to execute a write.

### Third Embodiment

A third embodiment is an addition to the countermeasure against the first inter-adjacent memory cell interference by the Foggy-Fine programming, using a different means from the first embodiment. Descriptions of parts in common with the first embodiment are omitted as appropriate.

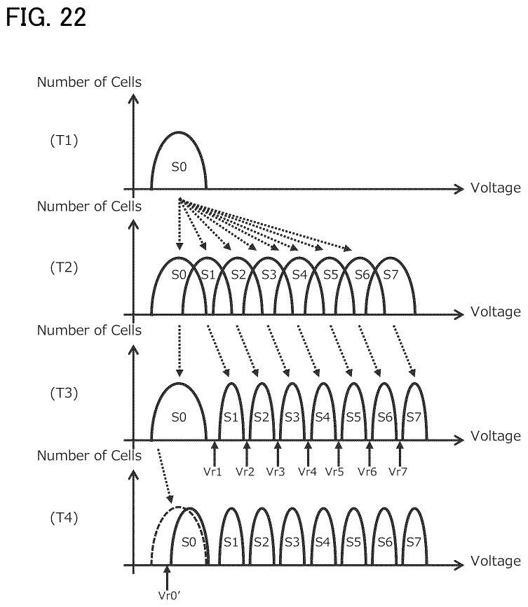

FIG. 22 is a drawing illustrating threshold distributions after programming in the third embodiment. In FIG. 22, (T1) illustrates the threshold distribution in the erase state, which is an initial state before programming. In FIG. 22, (T2) illustrates the threshold distributions after first-stage programming (Foggy programming). In FIG. 22, (T3) illustrates the threshold distributions after second-stage programming (Fine programming). The descriptions of (T1) through (T3) in FIG. 22 are the same as those in FIG. 16 and are omitted.

In FIG. 22, (T4) illustrates the threshold distributions after third-stage programming (reprogramming). As illustrated in (T4) in FIG. 22, in the third-stage programming, the control unit CTU of the NAND flash memory 40 performs a “weak” write on only the memory cells MC in the region S0 as the targets, according to the bit values to be written (stored) to the Lower page, the Middle page, and the Upper page, by adjusting the magnitude of the program voltage so as to decrease the threshold increase width by the application of one program voltage pulse. This increases only the threshold voltages of the memory cells MC located on the lower side of the distributions without increasing the threshold voltages of those located on the higher side of the distributions. In the third-stage programming, verification may be performed, or verification may be omitted. When the verification is performed, a verify voltage Vr0′ is set between a lower limit and an upper limit of the original region S0.

In the rewrite to the region S0, the memory cells MC to be the write targets are determined according to the write data of adjacent cells.

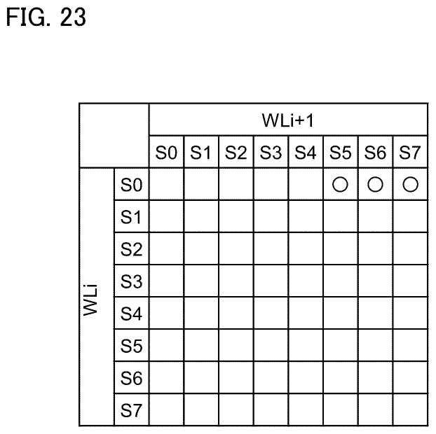

FIG. 23 illustrates an example of combinations of the threshold regions between the target cells and the adjacent cells that are the write targets for the third-stage programming in the third embodiment. In FIG. 23, the memory cells MC as the write targets are memory cells MC in the combinations marked with “○”, which have threshold voltages in the region S0 in the third-stage programming for the word line WLi and whose adjacent memory cells MC on the word line WLi+1 have threshold voltages in the region S5 to S7. In FIG. 23, the memory cells MC in other combinations without the mark are not the write targets. The combinations illustrated in FIG. 23 are an example, and the combinations to be the write targets may be enlarged or reduced depending on the strength of the inter-adjacent cell interference and the like.

When the memory cells MC as rewrite targets are determined, a verify operation may be further executed. For example, targets of the verify operation may be only those illustrated in FIG. 23 or may include other memory cells MC. In addition, in the verify operation, the verify voltage Vr0′ as described above may be applied to the selected word line WL. Further, those with a threshold voltage equal to or greater than the verify voltage Vr0′ may be excluded from the rewrite targets, and only those with a threshold voltage less than the verify voltage Vr0′ may be the rewrite targets. A result of the verify operation may be sent or need not be sent to the memory controller 30. When the result of the verify operation is sent to the memory controller 30, the result of the verify operation may be reflected in rewrite data, thereby excluding those with a threshold voltage equal to or greater than the verify voltage Vr0′ from the rewrite targets. When the result of the verify operation is not sent to the memory controller 30, computing may be performed inside the NAND flash memory 40, thereby excluding those with a threshold voltage equal to or greater than the verify voltage Vr0′ from the rewrite targets.

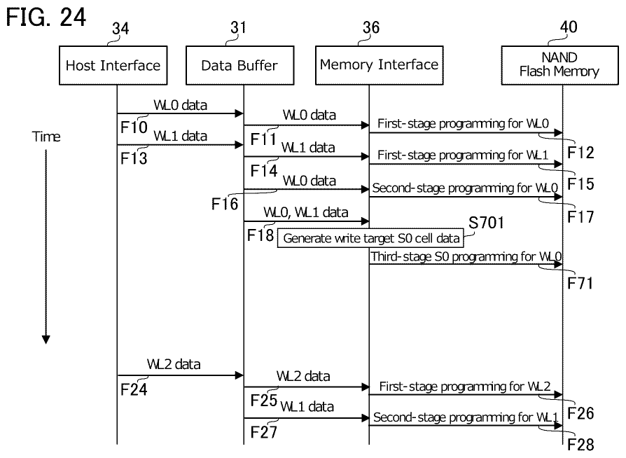

FIG. 24 illustrates a control flow of write data in the third embodiment.

The control flow illustrated in FIG. 24 is basically similar to the control flow illustrated in FIG. 18. However, in the control flow illustrated in FIG. 24, Step S701 is performed instead of Steps S501, S502, and S503, Flow F71 is performed instead of Flow F19, and Steps S502 and S503, and Flows F20, F21, F22, and F23 are not performed.

In the third-stage region S0 programming for the word line WL0, one page of data (rewrite data) is generated according to determination conditions illustrated in FIG. 23. In the one page of data, bits, where the write data for the word line WL0 and the write data for the word line WL1 correspond respectively to the region S0 and the regions S5 to S7, are write bits, and other bits are non-write bits (Step S701).

Next, the memory interface 36 sends this one page of data to the NAND flash memory 40 (Flow F71), and a one-page rewrite is executed for the word line WL0 in the NAND flash memory 40.

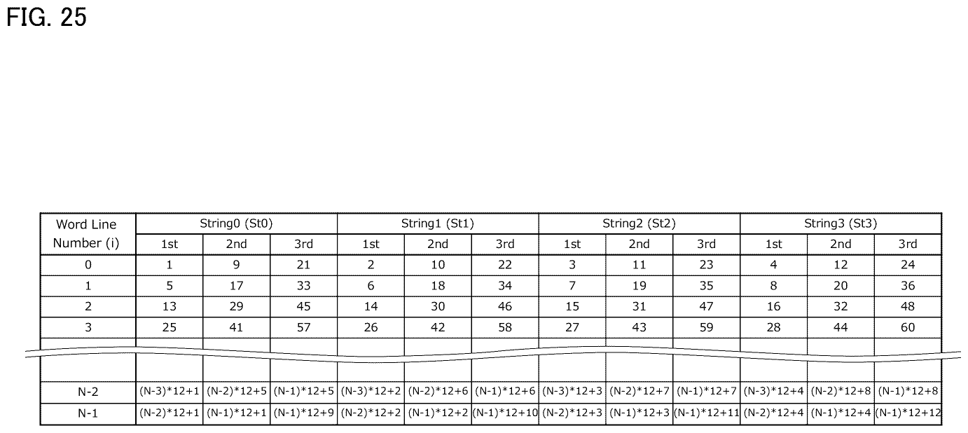

While the order in which the word lines are selected for programming in the third embodiment is the same as that in the first embodiment illustrated in FIGS. 15A and 15B, a modification in the third embodiment is illustrated in FIG. 25. This modification illustrates a case of performing the third-stage programming on the word line WLi after the second-stage programming for the next adjacent word line WLi+1. In the case of this order, a disadvantage is that the number of word lines WL over which the programming ranges to progress the stages is increased to four, therefore making the control more complicated. However, an advantage is that the risk of over-programming is reduced because the third-stage programming is executed after the final inter-adjacent cell interference is received from the adjacent word lines WL.

In the programming order illustrated in FIG. 25, the data for the word line WLi may have already been discarded from the data buffer (RAM 31) of the memory controller 30 when the third-stage programming is executed for the word line WLi. However, to determine the target memory cells MC, only the condition that the thresholds of the adjacent memory cells MC on the word line WLi+1 are in the region S5 to the region S7 may be used, and the condition that the thresholds of the memory cells MC on the word line WLi are in the region S0 may be excluded. This is because as long as the program voltage is adjusted to a voltage to an extent that finishes a weak write for the memory cells MC at a lower end of the region S0, even when all the memory cells MC on the word line WLi are the write targets, only the memory cells MC located at the lower end of the region S0 are subject to an actual write.

### Other Embodiments

FIG. 17 illustrates the combinations of the memory cells MC that are the rewrite targets in the first embodiment. FIG. 20 illustrates the combinations of the memory cells MC that are the rewrite targets in the second embodiment. FIG. 23 illustrates the combinations of the memory cells MC that are the rewrite targets in the third embodiment. However, these are merely examples, and the specific combinations and the like are adjustable as appropriate. For example, all the memory cells MC in the 21 combinations illustrated in FIG. 17, FIG. 20, and FIG. 23 may be the rewrite targets, or only a part of them may be the rewrite targets.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A memory system comprising:
a memory that includes:
a plurality of first memory cells;
a first word line connected to the plurality of first memory cells;
a plurality of second memory cells; and
a second word line connected to the plurality of second memory cells; and
a controller connected to the memory, wherein
the controller is configured to be able to store:
first write data used for a write to the plurality of first memory cells; and
second write data used for a write to the plurality of second memory cells, the write being performed after the write to the plurality of first memory cells,
the controller is configured to be able to calculate rewrite data based on the first write data and the second write data, and
the memory is configured to be able to perform:
a first write operation of performing a write on the plurality of first memory cells based on the first write data input from the controller; and
a rewrite operation of performing a write on a part of the plurality of first memory cells based on the rewrite data input from the controller.

2. The memory system according to claim 1, wherein
the rewrite operation is performed after the first write operation is performed at least once.

3. The memory system according to claim 1, wherein
the memory is configured to be able to further perform a second write operation of performing a write on the plurality of second memory cells based on the second write data input from the controller,
the second write operation is performed after the first write operation is performed at least once, and
the rewrite operation is performed after the second write operation is performed at least once.

4. The memory system according to claim 1, wherein
the memory further includes:
a plurality of third memory cells; and
a third word line connected to the plurality of third memory cells,
the first word line, the second word line, and the third word line are arranged in a first direction,
the first word line is disposed between the second word line and the third word line,
the controller is configured to be able to further store third write data used for a write to the plurality of third memory cells, the write being performed before the write to the plurality of first memory cells, and
the controller calculates the rewrite data based on the first write data, the second write data, and the third write data.

5. The memory system according to claim 1, wherein
at least one of a magnitude of a first write voltage applied to the first word line in the rewrite operation or an application time of the first write voltage to the first word line is settable based on the first write data and the second write data.

6. The memory system according to claim 2, wherein
a verify operation is performed in the rewrite operation, and the part of the plurality of first memory cells as a target of the rewrite operation is selected according to a result of the verify operation.

7. The memory system according to claim 1, wherein
a verify operation is performed in the rewrite operation, and a write is performed on the part of the plurality of first memory cells a plurality of times according to a result of the verify operation.

8. The memory system according to claim 1, wherein
the first write operation is performed dividedly into a plurality of stages.

9. The memory system according to claim 1, wherein
the controller includes a first storage region, and
the first write data and the second write data are stored in the first storage region.

10. The memory system according to claim 1, wherein
the memory includes a second storage region, and
the first write data and the second write data are stored in the second storage region.

11. The memory system according to claim 1, wherein
the memory includes a voltage supply unit,
the voltage supply unit applies a first program voltage pulse to the first word line in the first write operation,
the voltage supply unit applies a second program voltage pulse to the first word line in the rewrite operation, and
a magnitude of the second program voltage pulse is greater than a magnitude of the first program voltage pulse.

12. The memory system according to claim 1, wherein
the memory includes a voltage supply unit,
the voltage supply unit applies a first program voltage pulse to the first word line in the first write operation,
the voltage supply unit applies a second program voltage pulse to the first word line in the rewrite operation, and
an application time of the second program voltage pulse is longer than an application time of the first program voltage pulse.

13. A control method of a memory system, wherein
the memory system comprises:
a memory that includes:
a plurality of first memory cells;
a first word line connected to the plurality of first memory cells;
a plurality of second memory cells; and
a second word line connected to the plurality of second memory cells; and
a controller connected to the memory, wherein
the controller stores:
first write data used for a write to the plurality of first memory cells; and
second write data used for a write to the plurality of second memory cells, the write being performed after the write to the plurality of first memory cells,
the controller calculates rewrite data based on the first write data and the second write data, and
the memory performs:
a first write operation of performing a write on the plurality of first memory cells based on the first write data input from the controller; and
a rewrite operation of performing a write on a part of the plurality of first memory cells based on the rewrite data input from the controller.

14. The control method of the memory system according to claim 13, wherein
the rewrite operation is performed after the first write operation is performed at least once.

15. The control method of the memory system according to claim 13, wherein
the memory further performs a second write operation of performing a write on the plurality of second memory cells based on the second write data input from the controller,
the second write operation is performed after the first write operation is performed at least once, and
the rewrite operation is performed after the second write operation is performed at least once.

16. The control method of the memory system according to claim 13, wherein
the memory further includes:
a plurality of third memory cells; and
a third word line connected to the plurality of third memory cells,
the first word line, the second word line, and the third word line are arranged in a first direction,
the first word line is disposed between the second word line and the third word line,
the controller further stores third write data used for a write to the plurality of third memory cells, the write being performed before the write to the plurality of first memory cells, and
the controller calculates the rewrite data based on the first write data, the second write data, and the third write data.

17. The control method of the memory system according to claim 13, wherein
at least one of a magnitude of a first write voltage applied to the first word line in the rewrite operation or an application time of the first write voltage to the first word line is set based on the first write data and the second write data.

18. The control method of the memory system according to claim 14, wherein
a verify operation is performed in the rewrite operation, and the part of the plurality of first memory cells as a target of the rewrite operation is selected according to a result of the verify operation.

19. The control method of the memory system according to claim 13, wherein
a verify operation is performed in the rewrite operation, and a write is performed on the part of the plurality of first memory cells a plurality of times according to a result of the verify operation.

20. The control method of the memory system according to claim 13, wherein
the first write operation is performed dividedly into a plurality of stages.
